(19) United States
(12) Patent Application Publication
(10) Pub. No.: US 2026/0303048 A1
(43) Pub. Date: Oct. 1, 2026

(54) SUPERCONDUCTING PARAMETRIC GYRATORS

(71) Applicant: International Business Machines Corporation, Armonk, NY (US)

(72) Inventors: Matthew Beck, Danbury, CT (US); Joseph Robert Suttle, Chappaqua, NY (US); Ted Thorbeck, Elmsford, NY (US); Santino Carnevale, Stamford, CT (US); Joseph Finley, Rye Brook, NY (US); Michael Karunendra Selvanayagam, Ossining, NY (US); Corrado P. Mancini, Hopewell Junction, NY (US)

(21) Appl. No.: 19/097,170

(22) Filed: Apr. 1, 2025

(51) Int. Cl. H03H 7/00

(52) U.S. Cl. CPC H03H 7/002

(57) ABSTRACT

A device comprises a superconducting parametric gyrator circuit comprising a first I/O port, a second I/O port, and a parametric multipole bandpass filter circuit coupled between the first I/O port and the second I/O port. The parametric multipole bandpass filter circuit is responsive to a first control signal and a second control signal, which have a same frequency but different phases, to perform parametric frequency mixing of the first and second control signals with an input signal applied to the first I/O port or the second I/O port, to generate an output signal which has a same frequency as the input signal and a non-reciprocal phase shift based on a phase difference between the first control signal and the second control signal, and based on a direction of propagation of the input signal between the first I/O port and the second I/O port.

### BACKGROUND

This disclosure relates generally to quantum computing and, in particular, superconducting parametric gyrator devices, as well as microwave isolator and circulator devices that are implemented using superconducting gyrator devices. A superconducting quantum computing system is implemented using circuit quantum electrodynamics (QED) devices, which utilize the quantum dynamics of electromagnetic fields in superconducting circuits that include superconducting quantum bits, to generate and process quantum information. In general, superconducting quantum bits (qubits) are electronic circuits which are implemented using components such as superconducting tunnel junctions (e.g., Josephson junctions), inductors, and/or capacitors, etc., and which behave as quantum mechanical anharmonic (non-linear) oscillators with quantized states, when cooled to cryogenic temperatures.

In a quantum computing system which implements superconducting qubits, a quantum chip comprises cryogenic hardware which includes microwave components for controlling quantum states of the superconducting qubits, as well as reading out the quantum states of the superconducting qubits. For example, the cryogenic hardware includes microwave components such as isolator devices and circulator devices which provide non-reciprocal radio frequency (RF) signal transmission between multitudes of input/output (I/O) ports.

### SUMMARY

Exemplary embodiments of the disclosure include superconducting parametric gyrator devices and devices, such as microwave isolator devices and circulator devices, which are implemented using superconducting gyrator devices.

For example, an exemplary embodiment includes a device which comprises a superconducting parametric gyrator circuit comprising a first I/O port, a second I/O port, and a parametric multipole bandpass filter circuit coupled between the first I/O port and the second I/O port. The parametric multipole bandpass filter circuit is responsive to a first control signal and a second control signal, which have a same frequency but different phases, to perform parametric frequency mixing of the first and second control signals with an input signal applied to the first I/O port or the second I/O port, to generate an output signal which has a same frequency as the input signal and a non-reciprocal phase shift based on a phase difference between the first control signal and the second control signal, and based on a direction of propagation of the input signal between the first I/O port and the second I/O port.

Another exemplary embodiment includes a device which comprises a parametric multipole bandpass filter circuit comprising a first linear filter section coupled to a first I/O port, a second linear filter section, and a third linear filter section coupled to a second I/O port, a first parametric coupling circuit, and a second parametric coupling circuit. The first parametric coupling circuit parametrically couples the first linear filter section and the second linear filter section. The second parametric coupling circuit parametrically couples the second linear filter section and the third linear filter section.

Another exemplary embodiment includes a device which comprises a superconducting signal routing circuit. The superconducting signal routing circuit comprises a first hybrid coupler, a second hybrid coupler, a first parametric multipole bandpass filter circuit, and a second multipole bandpass filter circuit. The first parametric multipole bandpass filter circuit and the second multipole bandpass filter circuit are coupled, in parallel, between the first hybrid coupler and the second hybrid coupler. The first parametric multipole bandpass filter circuit comprises a first linear filter section, a second linear filter section, a third linear filter section, a first parametric coupling circuit, and a second parametric coupling circuit. The first parametric coupling circuit parametrically couples the first linear filter section and the second linear filter section. The second parametric coupling circuit parametrically couples the second linear filter section and the third linear filter section.

Other embodiments will be described in the following detailed description of exemplary embodiments, which is to be read in conjunction with the accompanying figures.

### BRIEF DESCRIPTION OF THE DRAWINGS

FIGS. 1A and 1B are high-level schematic illustrations of a superconducting parametric gyrator and modes of operation of the superconducting parametric gyrator, according to an exemplary embodiment of the disclosure.

FIG. 2A schematically illustrates a superconducting circulator device which is implemented using a superconducting parametric gyrator, according to an exemplary embodiment of the disclosure.

FIG. 2B schematically illustrates a superconducting isolator device which is implemented using a superconducting parametric gyrator, according to an exemplary embodiment of the disclosure.

FIG. 2C schematically illustrates a superconducting circulator device which is implemented using a superconducting parametric gyrator, according to another exemplary embodiment of the disclosure.

FIG. 2D schematically illustrates a superconducting circulator device which is implemented using a superconducting parametric gyrator, according to another exemplary embodiment of the disclosure.

FIG. 3A schematically illustrates a superconducting parametric gyrator device which comprises a parametric multipole bandpass filter circuit, according to an exemplary embodiment of the disclosure.

FIG. 3B schematically illustrates a superconducting parametric gyrator device which comprises a parametric multipole bandpass filter circuit, according to another exemplary embodiment of the disclosure.

FIG. 4 schematically illustrates a superconducting parametric gyrator device which comprises a parametric multipole bandpass filter circuit, according to another exemplary embodiment of the disclosure.

FIG. 5 schematically illustrates a superconducting parametric gyrator device which comprises a parametric multipole bandpass filter circuit, according to another exemplary embodiment of the disclosure.

FIGS. 6A, 6B, and 6C graphically illustrate simulated scattering parameters and operating modes of a superconducting parametric gyrator device, according to an exemplary embodiment.

FIG. 7A schematically illustrates a superconducting circulator device which is implemented using a superconducting parametric gyrator, according to another exemplary embodiment of the disclosure.

FIG. 7B schematically illustrates a superconducting isolator device which is implemented using a superconducting parametric gyrator, according to another exemplary embodiment of the disclosure.

FIGS. 8A, 8B, 8C, and 8D graphically illustrate simulated scattering parameters of a superconducting circulator device, according to an exemplary embodiment of the disclosure.

FIGS. 8E, 8F, and 8G graphically illustrate simulated scattering parameters of superconducting isolator devices, according to an exemplary embodiment of the disclosure.

FIG. 9 schematically illustrates a superconducting circulator device which is implemented using two superconducting parametric gyrators, according to another exemplary embodiment of the disclosure.

FIG. 10 graphically illustrates simulated scattering parameters of a superconducting isolator device, according to another exemplary embodiment of the disclosure.

FIG. 11 schematically illustrates a superconducting parametric gyrator device which comprises a parametric multipole bandpass filter circuit, according to another exemplary embodiment of the disclosure.

FIG. 12 graphically illustrates simulated scattering parameters of a superconducting gyrator device, according to another exemplary embodiment of the disclosure.

FIG. 13 schematically illustrates readout circuitry of a quantum processing system, which comprises superconducting isolator and circulator devices that are implemented using superconducting parametric gyrator circuits, according to an exemplary embodiment of the disclosure.

FIG. 14 schematically illustrates a quantum computing system which comprises superconducting isolator and circulator devices, according to an exemplary embodiment of the disclosure.

FIG. 15 schematically illustrates an exemplary architecture of a computing node which can host a quantum computing platform of the quantum computing system of FIG. 14, according to an exemplary embodiment of the disclosure.

### DETAILED DESCRIPTION

Exemplary embodiments of the disclosure will now be described in further detail with regard to superconducting parametric gyrator circuits and devices, as well as superconducting isolator and circulator circuits and devices, which are implemented using superconducting parametric gyrator circuits and devices.

For example, an exemplary embodiment includes a device which comprises a superconducting parametric gyrator circuit comprising a first I/O port, a second I/O port, and a parametric multipole bandpass filter circuit coupled between the first I/O port and the second I/O port. The parametric multipole bandpass filter circuit is responsive to a first control signal and a second control signal, which have a same frequency but different phases, to perform parametric frequency mixing of the first and second control signals with an input signal applied to the first I/O port or the second I/O port, to generate an output signal which has a same frequency as the input signal and a non-reciprocal phase shift based on a phase difference between the first control signal and the second control signal, and based on a direction of propagation of the input signal between the first I/O port and the second I/O port.

In another exemplary embodiment, which may be combined with one or more of the embodiments of the preceding paragraphs, the parametric multipole bandpass filter circuit comprises a first linear filter section, a second linear filter section, a third linear filter section, a first parametric coupling circuit, and a second parametric coupling circuit. The first parametric coupling circuit is configured to parametrically couple the first linear filter section and the second linear filter section. The second parametric coupling circuit is configured to parametrically couple the second linear filter section and the third linear filter section.

In another exemplary embodiment, which may be combined with one or more of the embodiments of the preceding paragraphs, the first parametric coupling circuit comprises a first non-linear inductance circuit which is responsive to the first control signal to cause a first parametric frequency conversion of a signal propagating between the first linear filter section and the second linear filter section. The second parametric coupling circuit comprises a second non-linear inductance circuit which is responsive to the second control signal to cause a second parametric frequency conversion of a signal propagating between the second linear filter section and the third linear filter section.

In another exemplary embodiment, which may be combined with one or more of the embodiments of the preceding paragraphs, the first non-linear inductance circuit and the second non-linear inductance circuit each comprise a direct current superconducting quantum interference device.

In another exemplary embodiment, which may be combined with one or more of the embodiments of the preceding paragraphs, the first non-linear inductance circuit and the second non-linear inductance circuit each comprise a single Josephson junction.

In another exemplary embodiment, which may be combined with one or more of the embodiments of the preceding paragraphs, the first linear filter section and the third linear filter section each comprise an immittance inverting bandpass filter having a first passband with a first center frequency. The second linear filter section comprises an immittance inverting bandpass filter having a second passband with a second center frequency, different from the first center frequency.

In another exemplary embodiment, which may be combined with one or more of the embodiments of the preceding paragraphs, the first parametric coupling circuit is responsive to the first control signal to perform a first parametric frequency conversion to convert a signal frequency between a first frequency in the first passband and a second frequency in the second passband, and apply a first phase shift based on a phase of the first control signal. The second parametric coupling circuit is responsive to the second control signal to perform a second parametric frequency conversion to convert a signal frequency between a first frequency in the first passband and a second frequency in the second passband, and apply a second phase shift based on a phase of the second control signal.

In another exemplary embodiment, which may be combined with one or more of the embodiments of the preceding paragraphs, one of the first control signal or the second control signal is an amplitude modulated control signal.

In another exemplary embodiment, which may be combined with one or more of the embodiments of the preceding paragraphs, the superconducting parametric gyrator circuit is a component of a superconducting isolator circuit or a component of a superconducting circulator circuit.

Another exemplary embodiment includes a device which comprises a parametric multipole bandpass filter circuit comprising a first linear filter section coupled to a first I/O port, a second linear filter section, and a third linear filter section coupled to a second I/O port, a first parametric coupling circuit, and a second parametric coupling circuit. The first parametric coupling circuit parametrically couples the first linear filter section and the second linear filter section. The second parametric coupling circuit parametrically couples the second linear filter section and the third linear filter section.

In another exemplary embodiment, which may be combined with one or more of the embodiments of the preceding paragraphs, the parametric multipole bandpass filter circuit is responsive to a first control signal applied to the first parametric coupling circuit and a second control signal applied to the second parametric coupling circuit, the first and second control signals having a same frequency and different phases, to perform parametric frequency mixing of the first and second control signals with an input signal applied to one of the first I/O port and the second I/O port, to generate an output signal which has a same frequency as the input signal and which has a phase shift which is based on (i) a phase difference between the first control signal and the second control signal, and (ii) a direction of propagation of the input signal between the first I/O port and the second I/O port.

In another exemplary embodiment, which may be combined with one or more of the embodiments of the preceding paragraphs, the first parametric coupling circuit comprises a first non-linear inductance circuit which is responsive to the first control signal to cause a first parametric frequency conversion of a signal propagating between the first linear filter section and the second linear filter section. The second parametric coupling circuit comprises a second non-linear inductance circuit which is responsive to the second control signal to cause a second parametric frequency conversion of a signal propagating between the second linear filter section and the third linear filter section.

In another exemplary embodiment, which may be combined with one or more of the embodiments of the preceding paragraphs, the first non-linear inductance circuit and the second non-linear inductance circuit each comprise a direct current superconducting quantum interference device.

In another exemplary embodiment, which may be combined with one or more of the embodiments of the preceding paragraphs, the first non-linear inductance circuit and the second non-linear inductance circuit each comprise a single Josephson junction.

In another exemplary embodiment, which may be combined with one or more of the embodiments of the preceding paragraphs, the first linear filter section and the third linear filter section each comprise an immittance inverting bandpass filter having a first passband with a first center frequency. The second linear filter section comprised of an immittance inverting bandpass filter having a second passband with a second center frequency, different from the first center frequency.

In another exemplary embodiment, which may be combined with one or more of the embodiments of the preceding paragraphs, the first parametric coupling circuit is responsive to the first control signal to perform a first parametric frequency conversion to convert a signal frequency between a first frequency in the first passband and a second frequency in the second passband, and apply a first phase shift based on a phase of the first control signal. The second parametric coupling circuit is responsive to the second control signal to perform a second parametric frequency conversion to convert a signal frequency between a first frequency in the first passband and a second frequency in the second passband, and apply a second phase shift based on a phase of the second control signal.

Another exemplary embodiment includes a device which comprises a superconducting signal routing circuit. The superconducting signal routing circuit comprises a first hybrid coupler, a second hybrid coupler, a first parametric multipole bandpass filter circuit, and a second multipole bandpass filter circuit. The first parametric multipole bandpass filter circuit and the second multipole bandpass filter circuit are coupled, in parallel, between the first hybrid coupler and the second hybrid coupler. The first parametric multipole bandpass filter circuit comprises a first linear filter section, a second linear filter section, a third linear filter section, a first parametric coupling circuit, and a second parametric coupling circuit. The first parametric coupling circuit parametrically couples the first linear filter section and the second linear filter section. The second parametric coupling circuit parametrically couples the second linear filter section and the third linear filter section.

In another exemplary embodiment, which may be combined with one or more of the embodiments of the preceding paragraphs, the second multipole bandpass filter circuit comprises a linear multipole bandpass filter circuit.

In another exemplary embodiment, which may be combined with one or more of the embodiments of the preceding paragraphs, the second multipole bandpass filter circuit comprises a second parametric multipole bandpass filter circuit, which is nominally identical in circuit architecture to the first parameter multipole bandpass filter circuit.

Advantageously, the exemplary superconducting parametric gyrator circuits/devices, and superconducting isolator and circulator circuits/devices based thereon, can be utilized in place of discrete ferrite-based gyrator, isolator and circulator devices to enable non-reciprocal phase shifting (gyration) and non-reciprocal transmission of signals in signal paths, e.g., qubit control and readout chains of a quantum computing system, and thereby reduce the footprint for implementing non-reciprocal signal transmission in such control and readout chains. The exemplary devices disclosed herein provide non-magnetic solutions for signal isolation and signal routing, and can be placed in relatively close proximity to a quantum processor and/or integrated therewith on an integrated circuit chip, while having a much smaller footprint as compared to discrete ferrite-based devices, and while providing non-reciprocal phase-shifting (gyration), signal routing, and signal isolation with electrical characteristics that are similar to corresponding ferrite-based isolation devices.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

Further, it is to be understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise quantum circuit elements (e.g., quantum processors, quantum bits, Josephson junction devices, Josephson parametric converters (JPCs), quantum-limited amplifiers (QLAs), qubit coupler circuitry, superconducting parametric gyrator circuits, superconducting isolator and circular, etc.), discrete microwave circuits (e.g., filters, diplexers, etc.), discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

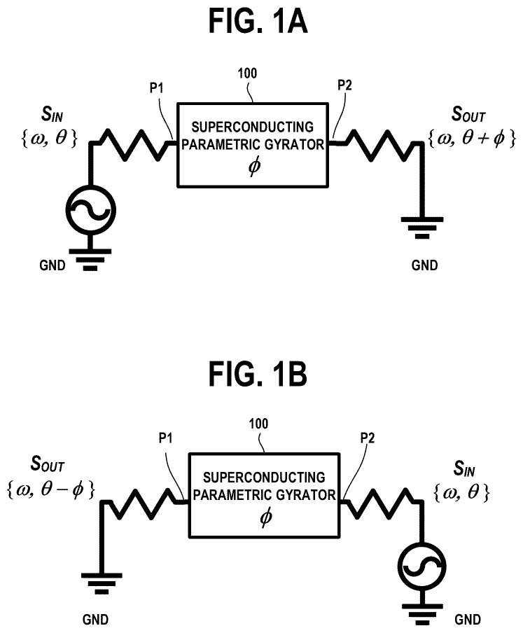

FIGS. 1A and 1B are high-level schematic illustrations of a superconducting parametric gyrator 100 and modes of operation of the superconducting parametric gyrator 100, according to an exemplary embodiment of the disclosure. In general, the superconducting parametric gyrator 100 is a non-reciprocal device which comprises a first port P1 and a second port P2, and which is configured to apply a phase shift φ to an input signal S_{IN} having an angular frequency ω and phase θ, and generate an output signal S_{OUT} having the same angular frequency ω, but with the applied phase shift φ. In particular, as illustrated in FIG. 1A, when the input signal S_{IN} is applied to the first port P1, the superconducting parametric gyrator 100 applies a positive phase shift +φ to generate the output signal S_{OUT} having the angular frequency ω and a phase θ+φ. On the other hand, as illustrated in FIG. 1B, when the input signal S_{IN} is applied to the second port P2, the superconducting parametric gyrator 100 applies a negative phase shift −φ to generate the output signal S_{OUT} having the angular frequency ω and a phase θ−φ. In this regard, the superconducting parametric gyrator 100 is configured to generate a positive or negative phase shift ±, depending on a propagation direction (wave vector) of the input signal S_{IN}.

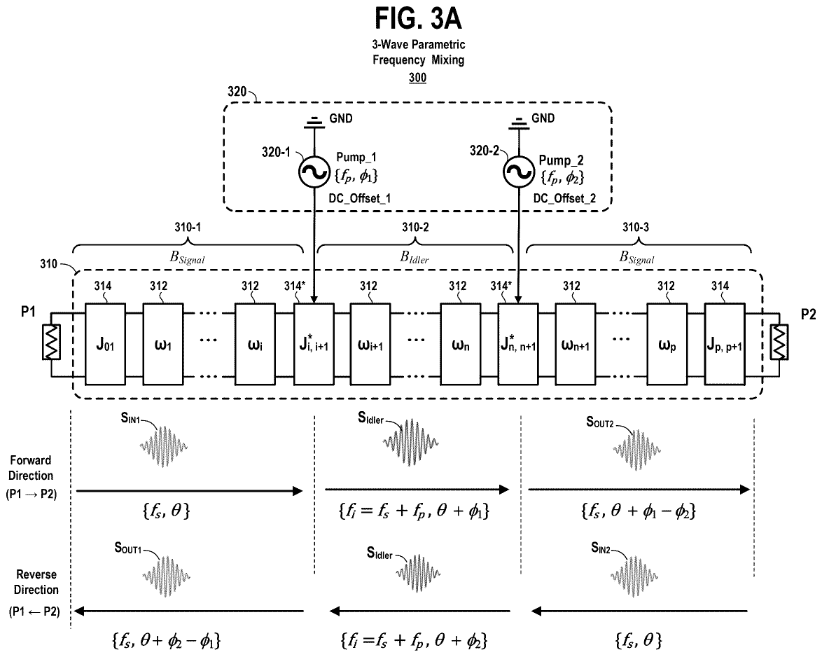

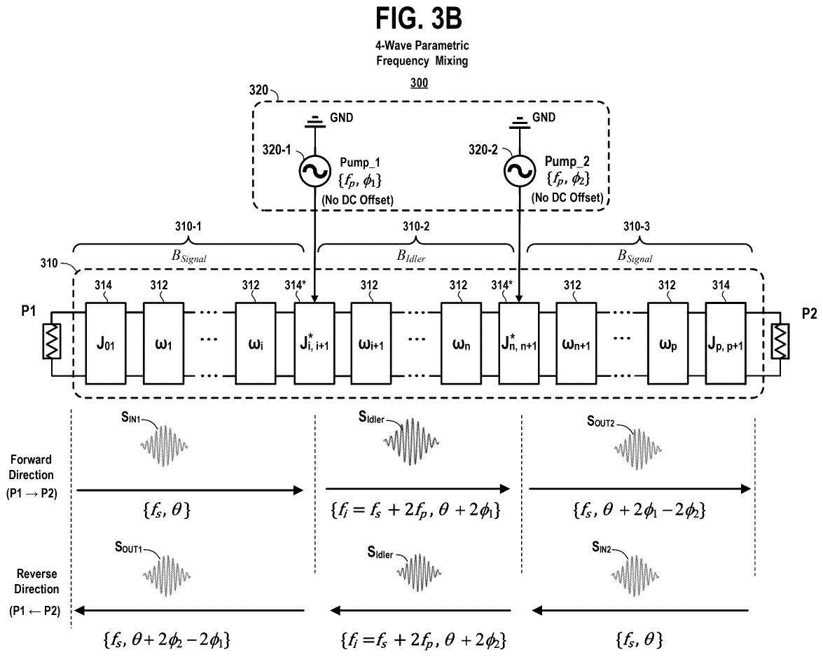

In some embodiments, the superconducting parametric gyrator 100 comprises a parametric multipole bandpass filter which is configured to produce gyration by implementing parametric couplers to couple linear sections of the multipole bandpass filter, and driving the parametric couplers with pump control signals having the same frequency, but different phases to thereby perform parametric frequency mixing (e.g., three-wave mixing or four-wave mixing) to achieve gyration. The parametric couplers can be implemented using various types of non-linear devices to achieve parametric frequency mixing, including, but not limited to, single Josephson junctions, Josephson junction arrays, Josephson ring modulators (JRMs), superconducting nonlinear asymmetric inductive element (SNAIL) devices, superconducting quantum interference devices (SQUIDs), such as DC SQUIDS or RF SQUIDs, or SQUID arrays, etc. Exemplary embodiments of superconducting parametric gyrator circuits, which can be used for implementing the superconducting parametric gyrator 100, will be discussed in further detail below in conjunction with, e.g., FIGS. 3A, 3B, 4, 5, and 11.

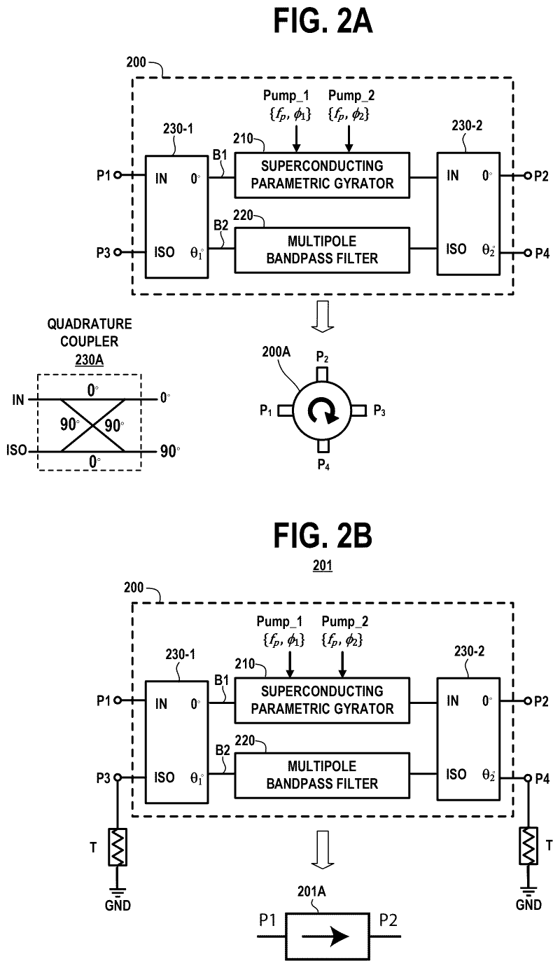

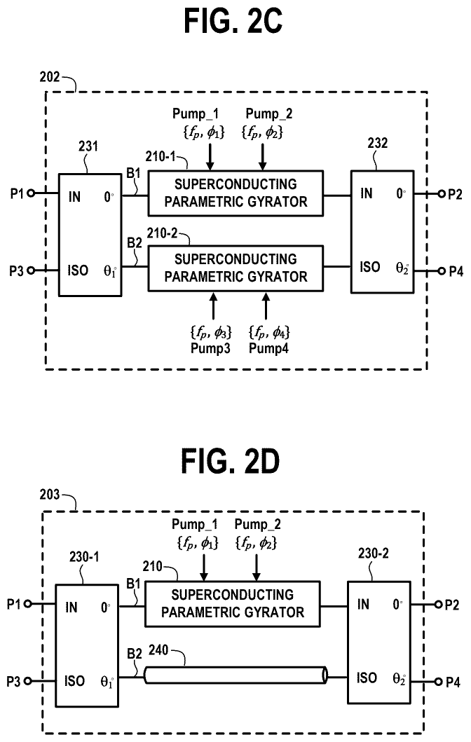

In other embodiments, superconducting parametric gyrator circuits as disclosed herein are utilized to implement broadband superconducting isolator devices and superconducting circulator devices. For example, FIGS. 2A, 2B, 2C and 2D are high-level schematic illustrations of superconducting isolator and circulator devices which can be implemented using superconducting parametric gyrator circuits and hybrid couplers, according to various embodiments of the disclosure.

In particular, FIG. 2A schematically illustrates a superconducting circulator device which is implemented using a superconducting parametric gyrator, according to an exemplary embodiment of the disclosure. In particular, FIG. 2A schematically illustrates a superconducting circulator device 200 which comprises a first hybrid coupler 230-1, a second hybrid coupler 230-2, a superconducting parametric gyrator 210, and a multipole bandpass filter 220. The superconducting circulator device 200 is a 4-port device comprising a first port P1, a second port P2, a third port P3, and a fourth port P4. The superconducting parametric gyrator 210 is disposed in a first branch B1 of the superconducting circulator device 200, while the multipole bandpass filter 220 is disposed in a second branch B2 of the superconducting circulator device 200, wherein the first and second branches B1 and B2 are coupled in parallel between the first hybrid coupler 230-1 and the second hybrid coupler 230-2. As explained in further detail below, the exemplary architecture of the superconducting circulator device 200 provides a “reflectionless” superconducting circulator device, wherein the reflection parameters S₁₁, S₂₂, S₃₃, and S₄₄ of the superconducting circulator device 200 are significantly suppressed both in-band and out-of-band of a given bandwidth of operation of the superconducting circulator device 200. The superconducting circulator device 200 comprises a 4-port superconducting circulator device, which corresponds to a 4-port circulator symbol 200A in FIG. 2A, wherein in operation, an RF signal entering port P₁ is routed to port P₂ (P₁→P₂), an RF signal entering port P₂ is routed to port P₃ (P₂→P₃), an RF signal entering port P₃ is routed to port P₄ (P₃→P₄), and an RF signal entering port P₄ is routed to port P₁(P₄→P₁), wherein the routing of an RF signal from one port to another port of the superconducting circulator device 200 is performed with high isolation from the other ports of the superconducting circulator device 200.

The first and second hybrid couplers 230-1 and 230-2 are 4-port devices, each comprising a first port (denoted IN port), a second port (denoted 0° port), a third port

$$( denoted {θ}_{1}^{°} or {θ}_{2}^{°} port ) ,$$

and a fourth port (denoted ISO port). As schematically shown in FIG. 2A, the first port P1 and the third port P3 of the superconducting circulator device 200 are connected to the first (IN) port and the fourth (ISO) port, respectively, of the first hybrid coupler 230-1, while the second port P2 and the fourth port P4 of the superconducting circulator device 200 are connected to the second (0°) port and the third

$$( {θ}_{2}^{°} ) port ,$$

respectively, of the second hybrid coupler 230-2. The superconducting parametric gyrator 210 is coupled to and between the second (0°) port of the first hybrid coupler 230-1 and the first (IN) port of the second hybrid coupler 230-2, while the multipole bandpass filter 220 is coupled to and between the third

$$( {θ}_{1}^{°} ) port$$

of the first hybrid coupler 230-1 and the fourth (ISO) port of the second hybrid coupler 230-2.

It is to be noted that in some embodiments, the first hybrid coupler 230-1 and the second hybrid coupler 230-2 each comprise a 90-degree hybrid coupler 230A (also known as a quadrature hybrid coupler), as schematically illustrated in FIG. 2A, wherein the third ports

$$( {θ}_{1}^{°} port and {θ}_{2}^{°} port )$$

of the respective first and second hybrid couplers 230-1 and 230-2 are both 90° ports

$$( i . e . , {θ}_{1}^{°} = {θ}_{2}^{°} = 90 ° ) .$$

The first hybrid coupler 230-1 and the second hybrid coupler 230-2 are passive microwave circuits which operate as either a power splitter or a power combiner. For example, when operating as a power splitter, the quadrature coupler 230A equally splits the power of an input microwave signal, which is applied to a given input port, into two microwave signals that are output from two output ports with equal power, with a 90° phase shift between the two output signals. For example, assume that a microwave signal is input to the first (IN) port of the first hybrid coupler 230-1 or the first (IN) port of second hybrid coupler 230-2, the input microwave signal is equally split into first and second microwave signals which are output from the 0° port and the 90° port, respectively, where the first and second output signals each have the same power (e.g., 50% of the input power), but a phase difference of 90°.

The first and second hybrid couplers 230-1 and 230-2 are electrically and mechanically symmetrical devices, whereby an input signal applied to any one of the four ports (IN port, 0° port, 90° port, or ISO port) will result in two equal amplitude signals which have a phase difference of 90° (for a quadrature coupler). For example, referring to the schematic illustration of the quadrature coupler 230A in FIG. 2A, if a microwave signal is input to the ISO port of the quadrature coupler 230A, the input microwave signal is equally split into first and second microwave output signals each having −3 dB power, wherein (i) the first microwave output signal is output from the 90° port of the quadrature coupler 230A with no phase shift, and (ii) the second microwave output signal is output from the 0° port of the quadrature coupler 230A with a 90° phase shift from the first microwave signal. The same applies to a microwave signal that is input to either the 0° port or the 90° port of the quadrature coupler 230A.

Furthermore, when operating as a power combiner, the quadrature coupler 230A combines microwave signals that are input to two ports thereof, and outputs a combined signal from at least one of the ports. For example, assume that a first microwave signal and a second microwave signal are input to the IN port and the ISO port, respectively, of the quadrature coupler 230A. Depending on the respective phases of the input first and second microwave signals, the signals will be combined (via constructive or destructive interference) and output from either the 0° port or the 90° port, or split between the 0° port and the 90° port, of the quadrature coupler 230A.

As noted above, in some embodiments, the superconducting parametric gyrator 210 comprises a parametric multipole bandpass filter which is configured to produce gyration by implementing parametric couplers to couple linear sections of the multipole bandpass filter, and by driving the parametric couplers with pump control signals having the same frequency, but different phases to thereby perform parametric frequency mixing (e.g., three-wave mixing or four-wave mixing) to achieve gyration. In particular, as schematically shown in FIG. 2A, the superconducting parametric gyrator 210 is driven by a first control signal (denoted Pump_1) and a second control signal (denoted Pump_2), wherein Pump_1 and Pump_2 have a same frequency fₚ, but wherein the first control signal Pump_1 has a first phase θ₁ and the second control signal Pump_2 has a second phase θ₂, which differs from the first phase φ₁. In some embodiments, as explained in further detail below, the first control signal Pump_1 is utilized to perform a first parametric frequency mixing process (e.g., frequency up-conversion), and the second control signal Pump_2 is utilized to perform a second parametric frequency mixing process (e.g., frequency down-conversion), wherein the superconducting parametric gyrator 210, in response to an input signal having a frequency fₛ and phase θ applied to an input thereof, will generate an output signal having the same frequency fₛ, but with a different phase of θ±Δ_{φ}, depending on the direction of RF power flow through the superconducting parametric gyrator 210, where Δ_{φ}=φ₁−φ₂ for a three-wave parametric frequency mixing mode of operation) or where Δ_{φ}=2(φ₁−φ₂) for a four-wave parametric frequency mixing mode of operation, the details of which will be explained in further detail below in conjunction with FIGS. 3A and 3B.

Moreover, in some embodiments, the multipole bandpass filter 220 comprises a linear, unity gain, multipole immittance inverting bandpass filter circuit, having a bandwidth that corresponds to an intended frequency range of operation of the superconducting parametric gyrator 210. Further, in some embodiments, the linear multipole bandpass filter 220 is configured to have a phase slope (i.e., change of phase as a function of frequency) in the second branch B2 which corresponds to the phase slope provided by the superconducting parametric gyrator 210 in the first branch B1. While both branches B1 and B2 are configured to have the same phase slope (or group delay), the first and second branches B1 and B2 are configured such that the linear multipole bandpass filter 220 is designed to introduce a constant phase offset (or relatively constant phase offset) in the second branch B2, in a desired frequency band of interest. The constant phase offset (in the frequency band of interest) between the first and second branches B1 and B2 serves to achieve a proper phase offset to properly implement the first and second 90-degree hybrid couplers 230-1 and 230-2. For example, in an illustrative, non-limiting embodiment, the phase offset between the first and second branches B1 and B2 can be 90 degrees, while the phase slope/group delay of the first and second branches B1 and B2 is the same.

It is to be noted, however, that depending on the phase offset introduced by the linear multipole bandpass filter 220 in the second branch B1, in some embodiments, the one of the first and second hybrid couplers 230-1 and 230-2 can be a quadrature hybrid coupler, while the other one of the first and second hybrid couplers 230-1 and 230-2 can be a 180-degree hybrid coupler. For example, in some embodiments,

$${θ}_{1}^{°} = 90 ° and {θ}_{2}^{°} = 180 ° ,$$

while in other embodiments,

$${θ}_{1}^{°} = 180 ° and {θ}_{2}^{°} = 90 ° ,$$

to achieve the proper phase offsets that are needed to realize the desired destructive and constructing interference of output signals at the ports P1, P2, P3, and P4 during operation of the superconducting circulator device 200.

The circuit parameters of the superconducting parametric gyrator 210 and/or the multipole bandpass filter 220 can be tailored in optimization so that the first and second branches B1 and B2 of the superconducting circulator device 200 are configured to have the same “group delay” between the first and second hybrid couplers 230-1 and 230-2, which allows the signals propagating in the first and second branches B1 and B2 to be combined together in phase by the first and second hybrid couplers 230-1 and 230-2 and thereby implement the desired operation of the superconducting circulator device 200. It is to be noted that the term “group delay” refers to a time lag expired by different frequency components of a signal as it propagates along the first branch B1 or the second branch B2. The group delay denotes how much the envelope of the signal is delayed, where unlike phase delay which varies with frequency, group delay focuses on the overall time delay across the entire spectrum of frequency components of the signal.

Next, FIG. 2B schematically illustrates a superconducting isolator device which is implemented using a superconducting parametric gyrator, according to an exemplary embodiment of the disclosure. In particular, FIG. 2B schematically illustrates a superconducting isolator device 201 which implements the same nominal circuit architecture as the superconducting circulator device 200 of FIG. 2A, except that two ports, e.g., the third and fourth ports P3 and P4, are each terminated with a matched termination T. The matched terminations T can be on-chip (integrated) terminations, on-package terminations, or an off-package terminations. The superconducting isolator device 201 corresponds to a 2-port isolator symbol 201A in FIG. 2B, wherein in operation, an RF signal entering port P₁ is routed to port P₂ (P₁→P₂), but wherein an RF signal entering port P₂ is routed to port P₃ (P₂→P₃) where the RF signal is terminated with high isolation such that the transmission parameter S₁₂ is significantly suppressed.

It is to be noted that the superconducting isolator device 201 operates in the same or similar manner as the superconducting circulator device 200 of FIG. 2A, the details of which need not be repeated. In this regard, as explained in further detail below, the exemplary architecture of the superconducting isolator device 201 provides a “reflectionless” superconducting isolator device, wherein the reflection parameters S₁₁ and S₂₂ of the superconducting isolator device 201 are significantly suppressed both in-band and out-of-band of a given bandwidth of operation of the superconducting isolator device 201.

Next, FIG. 2C schematically illustrates a superconducting circulator device which is implemented using a superconducting parametric gyrator, according to another exemplary embodiment of the disclosure. In particular, FIG. 2C schematically illustrates a superconducting circulator device 202 which comprises a first hybrid coupler 231, a second hybrid coupler 232, a first superconducting parametric gyrator 210-1, and a second superconducting parametric gyrator 210-2. The superconducting circulator device 202 is a 4-port device comprising a first port P1, a second port P2, a third port P3, and a fourth port P4. The first superconducting parametric gyrator 210-1 is disposed in a first branch B1 of the superconducting circulator device 202, while the second superconducting parametric gyrator 210-2 is disposed in a second branch B2 of the superconducting circulator device 202, wherein the first and second branches B1 and B2 are coupled in parallel between the first hybrid coupler 231 and the second hybrid coupler 232. The superconducting circulator device 202 can be represented by the 4-port circulator symbol 200A in FIG. 2A, and operates in a similar manner with regard to routing RF signals between ports, as discussed above.

In some embodiments, the first superconducting parametric gyrator 210-1 and the second superconducting parametric gyrator 210-2 are nominally identical in circuit configuration and operation. The first superconducting parametric gyrator 210-1 is driven by the first control signal Pump_1 and the second control signal Pump_2, which have the same frequency fₚ, but different phases, e.g., the first phase φ₁ and the second phase φ₂. On the other hand, the second superconducting parametric gyrator 210-2 is driven by a third control signal Pump_3 and a fourth control signal Pump_4, which have the same frequency fₚ (as Pump_1 and Pump_2), and respective phases, e.g., a third phase θ₃ and a fourth phase φ₄ which differs from the third phase θ₃. The first and second superconducting parametric gyrators 210-1 and 210-2 perform the same functions as the superconducting parametric gyrator 210 (FIG. 2A), as discussed above. However, the superconducting circulator device 202 provides a circuit architecture which enables fine tuning of the different phases and/or the amplitudes of the control signals Pump_1, Pump_2, Pump_3, and/or Pump_4 to compensate for phase imbalances and/or amplitude imbalances of the first and second hybrid couplers 231 and 232.

With the exemplary circuit configuration of the superconducting circulator device 202 of FIG. 2C, one of the first and second hybrid couplers 231 and 232 comprises a 90° (quadrature) coupler, while the other of the first and second hybrid couplers 231 and 232 comprises a 180° hybrid coupler, wherein the 180° hybrid coupler is a four port device that is used either to equally split an input signal with a 180° phase shift between the ports or to combine two signals that are 180° apart in phase. For example, in some embodiments, the first hybrid coupler 231 comprises a quadrature coupler

$$( {θ}_{1}^{∘} = 90 ° ) ,$$

and the second hybrid coupler 232 comprises a 1800 hybrid coupler

$$( {θ}_{2}^{°} = 180 ° ) .$$

In other embodiments, the first hybrid coupler 231 comprises a 1800 hybrid coupler

$$( {θ}_{1}^{∘} = 180 ° ) ,$$

and the second hybrid coupler 232 comprises a quadrature hybrid coupler

$$( {θ}_{2}^{∘} = 90 ° ) .$$

In some embodiments, the first and second superconducting parametric gyrators 210-1 and 210-2 have nominally identical circuit architectures and provide the same phase slope/group delay in the first and second branches B1 and B2. In this regard, given the parallel configuration of the first and second superconducting parametric gyrators 210-1 and 210-2 between the first and second hybrid couplers 231 and 232, the implementation of a quadrature coupler and a 180-degree hybrid coupler results in the proper signal phasing to achieve the requisite constructive and destructive interference of signals that are combined by the first and second hybrid couplers 231 and 232 to thereby enable the desired signal routing in the superconducting circulator device 202.

It is to be noted that the exemplary circuit configuration of the superconducting circulator device 202 of FIG. 2C can be reused to implement a superconducting isolator device. For example, similar to the exemplary embodiment shown in FIG. 2B, the superconducting circulator device 202 of FIG. 2C can be used to implement a 2-port superconducting isolator device by terminating each of two ports, e.g., the third and fourth ports P3 and P4, with a matched termination T, wherein in operation, an RF signal entering port P₁ is routed to port P₂ (P₁→P₂), but wherein an RF signal entering port P₂ is routed to port P₃ (P₂→P₃) where the RF signal is terminated with high isolation such that the transmission parameter S₁₂ is significantly suppressed. It is to be further noted that the exemplary architecture of the superconducting circulator device 202 provides a “reflectionless” superconducting circulator device (or superconducting isolator device), wherein the reflection parameters S₁₁, S₂₂, S33, and S44 of the superconducting circulator device 202 (or the reflection parameters S₁₁ and S₂₂ of a superconducting isolator device implemented using the superconducting circulator device 202) are significantly suppressed both in-band and out-of-band of a given bandwidth of operation of the superconducting circulator device 202 (or superconducting isolator device). The “reflectionless” device architecture is achieved at least in part by setting the bandwidth of the hybrid couplers to provide wideband operation, wherein the bandwidth of the hybrid couplers can be readily extended using common microwave design techniques.

Next, FIG. 2D schematically illustrates a superconducting isolator device which is implemented using a superconducting parametric gyrator, according to another exemplary embodiment of the disclosure. In particular, FIG. 2D schematically illustrates a superconducting circulator device 203 which is similar to the superconducting circulator device 200 of FIG. 2A, except that the superconducting circulator device 203 implements a delay transmission line 240 in the second branch B2 (in place of the multipole bandpass filter 220 in FIG. 2A). The electrical parameters of the delay transmission line 240 are tailored to enable impedance matching and to achieve a group delay in the second branch B2 which corresponds to the group delay in the first branch B1, to allow the signals propagating in the first and second branches B1 and B2 to be combined together in phase by the first and second hybrid couplers 230-1 and 230-2, as discussed above, and thereby implement the desired operation of the superconducting circulator device 202.

It is to be noted that the exemplary circuit configuration of the superconducting circulator device 203 of FIG. 2D can be reused to implement a superconducting isolator device. For example, similar to the exemplary embodiment shown in FIG. 2B, the superconducting circulator device 203 of FIG. 2D can be used to implement a 2-port superconducting isolator device by terminating two ports, e.g., the third and fourth ports P3 and P4, with a matched termination T, wherein in operation, an RF signal entering port P₁ is routed to port P₂ (P₁→P₂).

As noted above, the superconducting parametric gyrator circuits shown in FIGS. 1 and 2A-2D can be implemented using parametric multipole bandpass filter circuits which are configured to produce gyration by implementing parametric couplers to couple linear sections of the multipole bandpass filter, and driving the parametric couplers with pump control signals having the same frequency, but different phases to thereby perform parametric frequency mixing (e.g., three-wave mixing or four-wave mixing) to achieve gyration. In this regard, exemplary embodiments of superconducting parametric gyrator circuits which implement parametric multipole bandpass filter circuits, will now be discussed in further detail in conjunction with, e.g., FIGS. 3A, 3B, 4, 5, and 11.

In particular, FIG. 3A schematically illustrates a superconducting parametric gyrator device 300, according to an exemplary embodiment of the disclosure. The superconducting parametric gyrator device 300 comprises a parametric multipole bandpass filter 310 which is operated under the control of a control system 320 which comprises first and second control signal generators 320-1 and 320-2 that generate respective first and second control signals (denoted Pump_1 and Pump_2) which are applied to the parametric multipole bandpass filter 310. The parametric multipole bandpass filter 310 comprises a first I/O port (P1), a second I/O port (P2), and a multipole bandpass filter network comprising a plurality of resonator circuits 312 (sequentially denoted ω₁, . . . ωₚ), and a plurality of coupling circuits 314 and 314* (sequentially denoted J₀₁, . . . , J_{p,p+1}), wherein the coupling circuits (J₀₁, . . . , J_{p,p+1}) include linear coupling circuits 314 (alternatively, linear couplers 314), and parametric coupling circuits 314* (alternatively, parametric couplers 314*), wherein p denotes the number of “poles” of the parametric multipole bandpass filter 310, and p+1 denotes the total number of the linear and parametric coupling circuits 314 and 314* of the parametric multipole bandpass filter 310.

In some embodiments, the parametric multipole bandpass filter 310 comprises an admittance inverting multipole bandpass filter network (or more generally, an immittance inverting multipole bandpass filter network) which comprises an alternating sequence of resonator circuits and admittance inverter coupling circuits, wherein each resonator circuit 312 is coupled between two adjacent coupling circuits (e.g., two adjacent linear couplers 314 or two adjacent linear and parametric couplers 314 and 314*. In general, the coupling circuits (J₀₁, . . . , J_{p,p+1}) function as impedance matching circuits to match the impedance between adjacent resonator circuits, to match impedances between the first I/O port P1 and the resonator circuit ω₁, and between the second I/O port P2 and the resonator circuit ωₚ. The linear couplers 314 can be implemented using capacitive π-networks, inductive π-networks, and/or quarter-wavelength transmission lines. It is to be noted that while the exemplary superconducting parametric gyrator circuits, and superconducting circulator and isolator devices are illustrated herein as implementing immittance inverting multipole bandpass filter networks, in other embodiments, superconducting parametric gyrator circuits, and superconducting circulator and isolator devices can be implemented using other bandpass filter network topologies which are suitable for the intended applications as described herein.

Moreover, as schematically illustrated in FIG. 3A, the parametric multipole bandpass filter 310 comprises a first filter section 310-1, a second filter section 310-2, and a third filter section 310-3. The first filter section 310-1 and the second filter section 310-2 are coupled via a first parametric coupler

$$( denoted {J}_{i , i + 1}^{*} ) ,$$

wherein the first parametric coupler

$${J}_{i , i + 1}^{*}$$

is configured to parametrically couple the resonator circuits ωᵢ and ωᵢ₊₁ of the respective first and second filter sections 310-1 and 310-2. The second filter section 310-2 and the third filter section 310-3 are coupled via a second parametric coupler

$$( denoted {J}_{n , n + 1}^{*} ) ,$$

wherein the second parametric coupler

$${J}_{n , n + 1}^{*}$$

is configured to parametrically couple the resonator circuits βₙ and ωₙ₊₁ of the respective second and third filter sections 310-2 and 310-3. The first parametric coupler

$${J}_{i , i + 1}^{*}$$

is driven by the first control signal Pump_1 which has a pump frequency fₚ and a first phase φ₁. The second parametric coupler

$${J}_{n , n + 1}^{*}$$

is driven by the second control signal Pump_2 which has the same pump frequency fₚ and a second phase φ₂ which differs from the first phase φ₁. In addition, for purposes of implementing three-wave parametric frequency mixing, the first and second control signals Pump_1 and Pump_2 have respective first and second DC offsets, denoted DC_Offset_1 and DC_Offset_2.

The parametric multipole bandpass filter 310 comprises a “multiband” bandpass filter network which is configured to include a signal passband (denoted B_{Signal}) and an idler passband (denoted B_{Idler}). For example, the first filter section 310-1 of the parametric multipole bandpass filter 310 is configured to have a center frequency fₛ center (or signal frequency fₛ) of the signal passband B_{Signal} of the superconducting parametric gyrator device 300. Similarly, the third filter section 310-3 of the parametric multipole bandpass filter 310 is configured to have the center frequency fₛ of the signal passband B_{Signal} of the superconducting parametric gyrator device 300. For example, in an illustrative, non-limiting embodiment, the center frequency fₛ can be 7.2 GHz.

On the other hand, the second filter section 310-2 of the parametric multipole bandpass filter 310 is configured to have a center frequency fᵢ (or idler frequency fᵢ) of the idler passband B_{Idler} of the superconducting parametric gyrator device 300, wherein for three-wave parametric frequency mixing, the idler frequency fᵢ=fₛ+fₚ. For example, in an illustrative, non-limiting embodiment, the pump frequency fₚ can be 3.0 GHz, where the idler frequency fᵢ=fₛ+fₚ=7.2 GHz+3.0 GHz=10.2 GHz. In this regard, in some embodiments, the superconducting parametric gyrator device 300 is engineered such that the idler frequency fᵢ of the second filter section 310-2 is greater than (above) that the center signal frequency fₛ of the first and third filter sections 310-1 and 310-3. However, in other embodiments, the superconducting parametric gyrator device 300 can be engineered such that the idler frequency fᵢ of the second filter section 310-2 is less than (below) the center signal frequency fₛ of the first and third filter sections 310-1 and 310-3.

During operation of the superconducting parametric gyrator device 300, the first parametric coupler

$${J}_{i , i + 1}^{*}$$

is configured to perform a first frequency mixing process (e.g., a first parametric frequency conversion process) in response to the first pump control signal Pump_1, and the second parametric coupler

$${J}_{n , n + 1}^{*}$$

is configured to perform a second frequency mixing process (e.g., a second parametric frequency conversion process) in response to the second pump control signal Pump_2. Depending on the direction of flow of an RF input signal (e.g., forward direction from the first I/O port P1 to the second I/O port P2, or reverse direction from the second I/O port P2 to the first I/O port P1), the first parametric coupler

$${J}_{i , i + 1}^{*}$$

will perform either a parametric frequency up-conversion process or a parametric frequency down-conversion process, while the second parametric coupler

$${J}_{n , n + 1}^{*}$$

will perform either a parametric frequency down-conversion process or a parametric frequency up-conversion process.

By way of example, FIG. 3A schematically illustrates a mode of operation (three-wave parametric mixing mode) of the superconducting parametric gyrator device 300 in which the first parametric coupler

$${J}_{i , i + 1}^{*}$$

and the second parametric coupler

$${J}_{n , n + 1}^{*}$$

are configured to perform three-wave parametric frequency mixing, in particular, three-wave parametric frequency conversion. For example, in the forward direction (P1→P2), when an input RF signal (denoted S_{IN1}) having a signal frequency fₛ and phase θ, is applied to the first I/O port P1, the superconducting parametric gyrator device 300 will generate at the second I/O port P2, an output signal (denoted S_{OUT2}) having the same signal frequency fₛ, but with a phase of θ+φ₁−φ₂, wherein the phase θ is shifted by an amount equal to the difference between the first phase φ₁ and the second phase φ₂ of the respective first and second pump signals Pump_1 and Pump_2. In the forward direction, the first parametric coupler

$${J}_{i , i + 1}^{*}$$

performs a parametric frequency up-conversion process to convert Smi to an idler signal (denoted S_{Idler}) having an idler frequency fᵢ=fₛ+fₚ and a phase of θ+φ₁. In addition, the second parametric coupler

$${J}_{n , n + 1}^{*}$$

performs a parametric frequency down-conversion process to convert S_{Idler} to the output signal S_{OUT2} which has the same signal frequency fₛ as the input signal Smi but with a phase of θ+φ₁−φ₂ (where the phase θ is shifted by φ₁−φ₂)).

On the other hand, in the reverse direction (P1←P2), when an input RF signal (denoted S_{IN2}) having a signal frequency fₛ and phase θ, is applied to the second I/O port P2, the superconducting parametric gyrator device 300 will generate at the first I/O port P1, an output signal (denoted S_{OUT1}) having the same signal frequency fₛ, but with a phase of θ+φ₂−φ₁, wherein the phase θ is shifted by an amount equal to the difference between the second phase φ₂ and the first phase φ₁ of the respective second and first pump signals Pump_2 and Pump_1. In the reverse direction, the second parametric coupler

$${J}_{n , n + 1}^{*}$$

performs a parametric frequency up-conversion process to convert S_{IN2} to an idler signal S_{Idler} having an idler frequency fᵢ=_{f}+fₚ and a phase of θ+φ₂. In addition, the first parametric coupler

$${J}_{i , i + 1}^{*}$$

performs a parametric frequency down-conversion process to convert S_{Idler} to the output signal Souri which has the same signal frequency fₛ as the input signal S_{IN2} but with a phase of θ+φ₂−φ₁ (where the phase θ is shifted by φ₂−φ₁)).

As described above, FIG. 3A schematically illustrates an exemplary mode of operation of the superconducting parametric gyrator device 300 in which the first parametric coupler

$${J}_{i , i + 1}^{*}$$

and the second parametric coupler

$${J}_{n , n + 1}^{*}$$

are configured to perform three-wave parametric frequency mixing, in particular, three-wave parametric frequency conversion, to achieve non-reciprocal gyration, whereby an input signal having a frequency fₛ and phase θ applied to one of the first and second I/O ports P1 and P2 thereof, will generate an output signal having the same frequency fₛ, but with phase of θ±Δ_{φ}, where Δ_{φ}=φ₁−φ₂, depending on the direction of RF power flow through the superconducting parametric gyrator device 300. In other embodiments, the superconducting parametric gyrator device 300 can be configured to perform four-wave parametric frequency mixing, in particular, four-wave parametric frequency conversion, using the same first and second pump control signals Pump_1 and Pump_2 as shown in FIG. 3A, but with no DC offsets. When configured to perform four-wave parametric frequency mixing, the superconducting parametric gyrator device 300 will convert an input signal having a frequency fₛ and phase θ (which is applied to one of the first and second I/O ports P1 and P2 thereof) to an output signal having the same frequency fₛ, but with phase of θ±Δ_{2φ}, where Δ_{2φ}=2(φ₁−φ₂), depending on the direction of RF power flow through the superconducting parametric gyrator device 300. Moreover, when configured to perform four-wave parametric frequency mixing, the first parametric coupler

$${J}_{i , i + 1}^{*}$$

and the second parametric coupler

$${J}_{n , n + 1}^{*}$$

will perform a parametric frequency up-conversion process to convert an input signal (e.g., S_{IN1} or S_{IN2}) to an idler signal having a frequency fᵢ=fₛ+2fₚ.

For example, FIG. 3B schematically illustrates a superconducting parametric gyrator device which comprises a parametric multipole bandpass filter circuit, according to another exemplary embodiment of the disclosure. In particular, FIG. 3B schematically illustrates the superconducting parametric gyrator device 300 of FIG. 3A, but where the superconducting parametric gyrator device 300 is configured to perform four-wave parametric frequency mixing, in particular, four-wave parametric frequency conversion, using the same first and second pump control signals Pump_1 and Pump_2 as shown in FIG. 3A, but with no DC offsets. As shown in FIG. 3B, in a four-wave parametric mixing mode of operation, in the forward direction (P1→P2), when an input RF signal (denoted S_{IN1}) having a signal frequency fₛ and phase θ, is applied to the first I/O port P1, the superconducting parametric gyrator device 300 will generate at the second I/O port P2, an output signal (denoted S_{OUT2}) having the same signal frequency fₛ, but with a phase of θ+2φ₁−2φ₂, wherein the phase θ is shifted by an amount equal to 2× the difference between the first phase φ₁ and the second phase φ₂ of the respective first and second pup signals Pump_1 and Pump_2. In the forward direction, the first parametric coupler

$${J}_{i , i + 1}^{*}$$

performs a parametric frequency up-conversion process to convert S_{IN1} to an idler signal (denoted S_{Idler}) having an idler frequency fᵢ=fₛ+2fₚ and a phase of θ+2φ₁. In addition, the second parametric coupler

$${J}_{n , n + 1}^{*}$$

performs a parametric frequency down-conversion process to convert S_{Idler} to the output signal S_{OUT2} which has the same signal frequency fₛ as the input signal Smi but with a phase of θ+2φ₁−2φ₂ (where the phase θ is shifted by 2(φ₁−φ₂)).

On the other hand, in the reverse direction (P2 →P1), when an input RF signal (denoted S_{IN2}) having a signal frequency fₛ and phase θ, is applied to the second I/O port P2, the superconducting parametric gyrator device 300 will generate at the first I/O port P1, an output signal (denoted S_{OUT1}) having the same signal frequency fₛ, but with a phase of θ+2φ₂−2φ₁, wherein the phase θ is shifted by an amount equal to 2× the difference between the second phase φ₂ and the first phase φ₁ of the respective second and first pump signals Pump_2 and Pump_1. In the reverse direction, the second parametric coupler

$${J}_{n , n + 1}^{*}$$

performs a parametric frequency up-conversion process to convert S_{IN2} to an idler signal S_{Idler} having an idler frequency fᵢ=fₛ+2fₚ and a phase of θ+2φ₂. In addition, the first parametric coupler

$${J}_{i , i + 1}^{*}$$

performs a parametric frequency down-conversion process to convert S_{Idler} to the output signal S_{OUT1} which has the same signal frequency fₛ as the input signal S_{IN2} but with a phase of θ+2φ₂−2φ₁ (where the phase θ is shifted by 2(φ₂−φ₁)).

It is to be noted that while the parametric couplers 314* are generically shown in FIGS. 3A and 3B, the parametric couplers 314* can be implemented using various types of non-linear devices to achieve parametric frequency mixing (e.g., parametric frequency conversion). For example, as noted above, each of the parametric couplers 314* can be implemented using, for example, a single Josephson junction, a Josephson junction array, a JRM, a SNAIL device, a SQUID, such as DC SQUIDS or RF SQUIDs, or a SQUID array, etc. Moreover, while the exemplary embodiments of FIGS. 3A and 3B (and other embodiments discussed herein) illustrate parametric multipole bandpass filters that implement admittance inverting multipole bandpass filter networks, where the coupling circuits are shown as admittance inverters J, in other embodiments, the multipole bandpass filter networks can be implemented as impedance inverting multipole bandpass filter networks, wherein the coupling circuits are implemented using impedance inverters instead of admittance inverters. In this regard, the exemplary multipole bandpass filter networks as discussed herein can be implemented using immittance inverting multipole bandpass filters, wherein the terms “immittance inverting” or “immittance inverter” broadly denote terms such as admittance inverting, admittance inverter, impedance inverting, or impedance inverter.

It is to be understood that FIGS. 3A and 3B schematically illustrate a high-level architecture of a superconducting parametric gyrator device 300 which implements a parametric multipole bandpass filter with superconducting parametric couplers to provide non-reciprocal phase-shift (gyration) depending on the direction of RF signal flow through the superconducting parametric gyrator devices. In this regard, it is to be noted that the number of linear resonators and linear coupling circuits in each of the first, second, and third filter sections 310-1, 310-2, 310-3 can vary depending on the application and desired device performance. In this regard, it is to be appreciated that various embodiments of superconducting parametric gyrator circuits can be implemented based on the general architecture shown in FIGS. 3A and 3B.

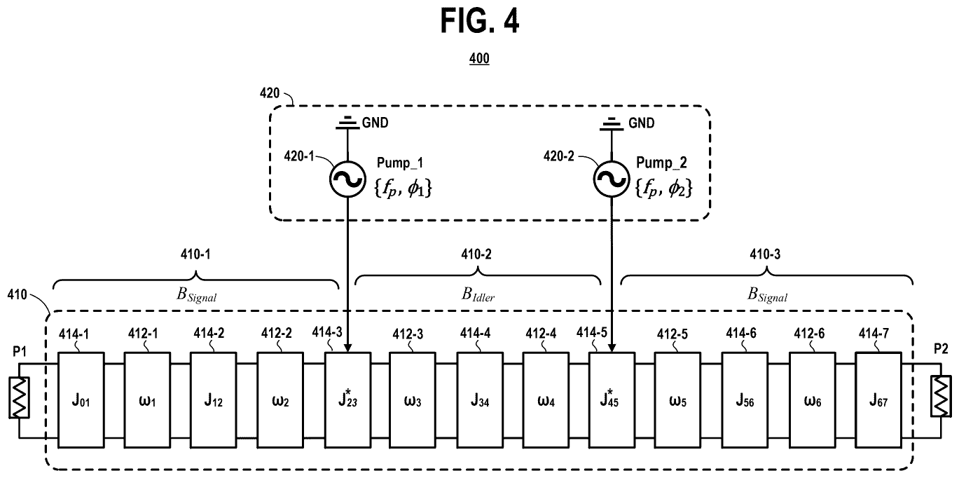

For example, FIG. 4 schematically illustrates a superconducting parametric gyrator device which comprises a parametric multipole bandpass filter circuit, according to another exemplary embodiment of the disclosure. In particular, FIG. 4 schematically illustrates a superconducting parametric gyrator device 400 which comprises a parametric multipole bandpass filter 410 which comprises a 6-pole bandpass filter network configuration based on the filter architecture of FIGS. 3A and 3B, and which is operated under the control of a control system 420 which comprises first and second control signal generators 420-1 and 420-2 that generate respective first and second control signals (denoted Pump_1 and Pump_2) which are applied to the parametric multipole bandpass filter 410. The parametric multipole bandpass filter 410 comprises a first I/O port P1, a second I/O port P2, and a multipole bandpass filter network comprising six (6) resonator circuits 412-1, 412-2, 412-3, 412-4, 412-5, and 412-6 (sequentially denoted as ω₁, ω₂, ω₃, ω₄, ω₅, and ω₆), and seven (7) coupling circuits 414-1, 414-2, 414-3, 414-4, 414-5, 414-6, and 414-7

$$( sequentially denoted {J}_{01} , {J}_{12} , {J}_{23}^{*} , {J}_{34} , {J}_{45}^{*} , {J}_{56} , and {J}_{67} ) ,$$

which include linear coupling circuits 414-1, 414-2, 414-4, 414-6, and 414-7 (linear couplers) and first and second parametric coupling circuits 414-3

$$( {J}_{23}^{*} )$$

and 414-5

$$( {J}_{45}^{*} )$$

(parametric couplers).

The parametric multipole bandpass filter 410 comprises a first filter section 410-1, a second filter section 410-2, and a third filter section 410-3, providing a multiband bandpass filter comprising an idler band Bidi, and signal bands B_{Signal}, as discussed above. FIG. 4 illustrates an exemplary embodiment in which the first, second, and third filter sections 410-1, 410-2, and 410-3 each comprise two resonator circuits (2 poles). The first filter section 410-1 and the second filter section 410-2 are coupled via the first parametric coupler 414-3. The second filter section 410-2 and the third filter section 410-3 are coupled via the second parametric coupler 414-5. The first parametric coupler 414-3 is driven by the first control signal Pump_1 which has a pump frequency fₚ and a first phase φ₁. The second parametric coupler 414-5 is driven by the second control signal Pump_2 which has the same pump frequency fₚ and a second phase φ₂ which differs from the first phase φ₁. In addition, as discussed above in conjunction with FIGS. 3A and 3B, the superconducting parametric gyrator device 400 can be operated in either (i) a three-wave parametric frequency mixing mode by adding first and second DC offsets to the first and second control signals Pump_1 and Pump_2, or (ii) a four-wave parametric frequency mixing mode by using first and second control signals Pump_1 and Pump_2 with no DC offset.

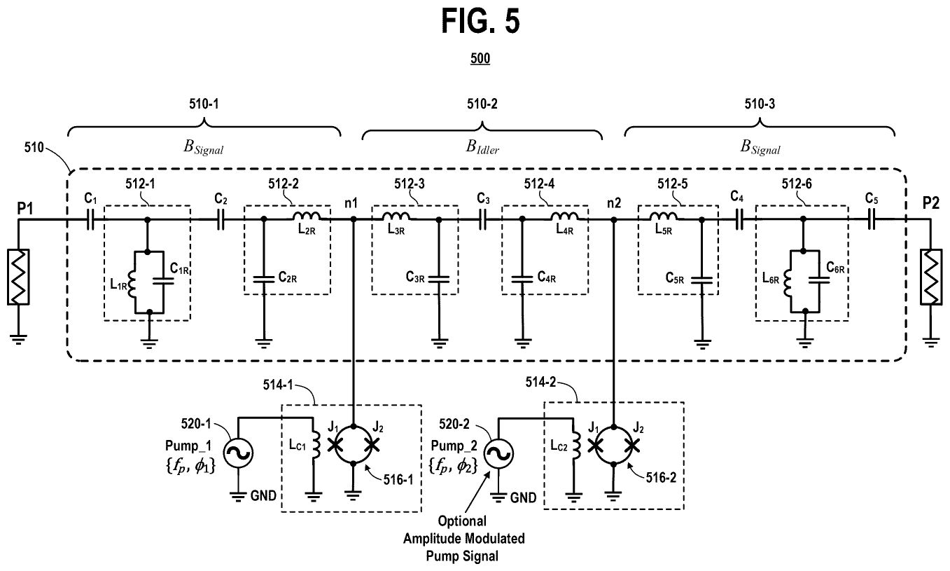

Next, FIG. 5 schematically illustrates a superconducting parametric gyrator device which comprises a parametric multipole bandpass filter circuit, according to another exemplary embodiment of the disclosure. In particular, FIG. 5 illustrates a schematic circuit implementation of a superconducting parametric gyrator device 500 which is based on the 6-pole bandpass filter network configuration of FIG. 4. The superconducting parametric gyrator device 500 comprises a parametric multipole bandpass filter 510, which is operated under the control of a control system which comprises first and second control signal generators 520-1 and 520-2 that generate respective first and second control signals (denoted Pump_1 and Pump_2). The parametric multipole bandpass filter 510 comprises a first I/O port P1, a second I/O port P2, and a multipole bandpass filter network comprising six (6) resonator circuits and seven (7) coupling circuits.

In particular, the parametric multipole bandpass filter 510 comprises a first resonator circuit 512-1, a second resonator circuit 512-2, a third resonator circuit 512-3, a fourth resonator circuit 512-4, a fifth resonator circuit 512-5, and a sixth resonator circuit 512-6 (collectively, resonator circuits 512). The coupling circuits comprise five (5) linear couplers implemented by coupling capacitors including a first coupling capacitor C₁, a second coupling capacitor C₂, a third coupling capacitor C₃, a fourth coupling capacitor C₄, and a fifth coupling capacitor C₅. In addition, the coupling circuits comprise two parametric couplers including a first parametric coupler 514-1 and a second parametric coupler 514-2. The first parametric coupler 514-1 is coupled to a first node n1 of the parametric multipole bandpass filter 510, and the second parametric coupler 514-2 is coupled to a second node n2 of the parametric multipole bandpass filter 510.

It is to be noted that FIG. 5 illustrates an exemplary embodiment in which the first and second parametric couplers 514-1 and 514-2 are implemented using DC-SQUIDS to perform 3-wave or 4-wave parametric frequency mixing operations of the superconducting parametric gyrator device 500. The first parametric coupler 514-1 comprises a first DC-SQUID 516-1 which is coupled to and between the first node n1 and ground (denoted GND). The second parametric coupler 514-2 comprises a second DC-SQUID 516-2 which is coupled to and between the second node n2 and ground GND. The first DC-SQUID 516-1 and the second DC-SQUID 516-2 each comprise a first Josephson junction J₁ and a second Josephson junction J₂, which are connected in parallel to form a superconducting loop (referred to as SQUID loop) through which an external magnetic flux (Φₑₓₜ) is passed to perform the parametric frequency mixing operations as discussed herein. Essentially, the first DC-SQUID 516-1 and the second DC-SQUID 516-2 each operate as a single Josephson junction with an effective critical current I_{CS} and Josephson energy E_{JS} which is tunable by inductively coupling an external magnetic flux (Φₑₓₜ) to the SQUID loop to perform non-linear frequency mixing operations. The Josephson junctions J₁ and J₂ have non-linear inductances, and may have the same, similar, or different critical currents.

As schematically shown in FIG. 5, the first DC-SQUID 516-1 is disposed adjacent to, and is inductively coupled to, a first coupling inductor L_{C1}. The second DC-SQUID 516-2 is disposed adjacent to, and is inductively coupled to, a second coupling inductor L_{C2}. The first coupling inductor L_{C1} is response to the first control signal Pump_1 to generate an external magnetic flux Φₑₓₜ which threads through the superconducting loop of the first DC-SQUID 516-1 to dynamically change the inductance of the first DC-SQUID 516-1 to perform parametric frequency mixing operations. Similarly, the first coupling inductor L_{C2} is response to the second control signal Pump_2 to generate an external magnetic flux Φₑₓₜ which threads through the superconducting loop of the second DC-SQUID 516-2 to dynamically change the inductance of the second DC-SQUID 516-1 to perform parametric frequency mixing operations.

The parametric multipole bandpass filter 510 comprises a first filter section 510-1, a second filter section 510-2, and a third filter section 510-3, providing a multiband bandpass filter network which comprises an idler band B_{Idile} and signal bands B_{Signal}, as discussed above. FIG. 5 illustrates an exemplary embodiment in which the first, second, and third filter sections 510-1, 510-2, and 510-3 each comprise two resonator circuits (2 poles). The resonator circuits 512 comprise LC resonator circuits. In particular, the first resonator circuit 512-1 comprises an inductor L_{1R} and a capacitor C_{1R}, the second resonator circuit 512-2 comprises an inductor L_{2R} and a capacitor C_{2R}, the third resonator circuit 512-3 comprises an inductor L_{3R} and a capacitor C_{3R}, the fourth resonator circuit 512-4 comprises an inductor L_{4R} and a capacitor C_{4R}, the fifth resonator circuit 512-5 comprises an inductor L_{5R} and a capacitor C_{5R}, and the sixth resonator circuit 512-6 comprises an inductor L_{6R} and a capacitor C_{6R}.

In addition, FIG. 5 illustrates an exemplary embodiment in which capacitive π-networks are utilized to implement linear capacitive coupling in the first, second, and third filter sections 510-1, 510-2, and 510-3. In particular, the first coupling capacitor C₁ is configured to linearly couple the first I/O port and the first resonator circuit 512-1, the second coupling capacitor C₂ is configured to linearly couple the first resonator circuit 512-1 and the second resonator circuit 512-2, the third coupling capacitor C₃ is configured to linearly couple the third resonator circuit 512-3 and the fourth resonator circuit 512-4, the fourth coupling capacitor C₄ is configured to linearly couple the fifth resonator circuit 512-5 and the sixth resonator circuit 512-6, and the fifth coupling capacitor C₅ is configured to linearly couple the sixth resonator circuit 512-6 and the second I/O port P2.

Furthermore, the first parametric coupler 514-1 is configured to parametrically couple the first filter section 510-1 and the second filter section 510-2, and the second parametric coupler 514-2 is configured to parametrically couple the second filter section 510-2 and the third filter section 510-3. In particular, the first parametric coupler 514-1 is configured to parametrically couple the second resonator circuit 512-2 and the third resonator circuit 512-3, and the second parametric coupler 514-2 is configured to parametrically couple the fourth resonator circuit 512-4 and the fifth resonator circuit 512-5. FIG. 5 schematically illustrates an exemplary embodiment in which inductive T networks are implemented to provide such parametric coupling.

For example, the parametric multipole bandpass filter 510 comprises a first inductive T network which is comprised of the inductors L_{2R} and L_{3R} (of the second and third resonator circuits 512-2 and 512-3), and the non-linear inductance of the first DC-SQUID 516-1, which are commonly coupled to the first node n1. In this configuration, the inductors L_{2R} and L_{3R} are essentially shunted to ground GND through the first DC-SQUID 516-1, whereby the first DC-SQUID 516-1 provides a parametric mutual coupling between the second and third resonator circuits 512-2 and 512-3. In addition, the parametric multipole bandpass filter 510 comprises a second inductive T network which is comprised of the inductors L_{4R} and L_{5R} (of the fourth and fifth resonator circuits 512-4 and 512-5), and the non-linear inductance of the second DC-SQUID 516-2, which are commonly coupled to the second node n2. In this configuration, the inductors L_{4R} and L_{5R} are essentially shunted to ground GND through the second DC-SQUID 516-2, whereby the second DC-SQUID 516-2 provides a parametric mutual coupling between the fourth and fifth resonator circuits 512-4 and 512-5.

It is to be noted that as discussed above in conjunction with FIGS. 3A and 3B, the superconducting parametric gyrator device 500 can be operated in either (i) a three-wave parametric frequency mixing mode by adding first and second DC offsets to the first and second control signals Pump_1 and Pump_2, or (ii) a four-wave parametric frequency mixing mode by using first and second control signals Pump_1 and Pump_2 with no DC offset. Moreover, it is to be noted that in some embodiments, the first and second control signal generators 520-1 and 520-2 are operated to continuously generate and apply the first and second control signals Pump_1 and Pump_2 to the respective first and second parametric couplers 514-1 and 514-2. However, in other embodiments, one of the first and second control signal generators 520-1 and 520-2 can be operated to apply an amplitude modulated control signal to one of the first and second parametric couplers 514-1 and 514-2 to enable pulse-shaping or amplitude modulation of the signal output from the superconducting parametric gyrator device 500. For example, as schematically shown in FIG. 5, the second control signal generator 520-2 can be configured to apply an amplitude modulated pump control signal to the second parametric coupler 514-2 to enable pulse-shaping or amplitude modulation of the signal output from the superconducting parametric gyrator device 500. Moreover, the phase and/or amplitude of Pump_1 and/or Pump_2 can be adjusted, as needed, to optimize performance of the superconducting parametric gyrator device 500.

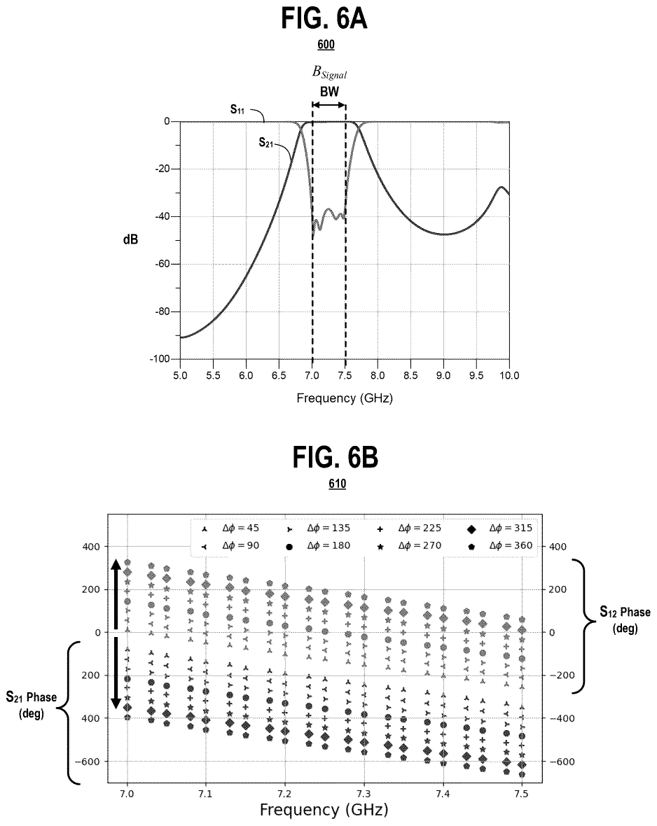

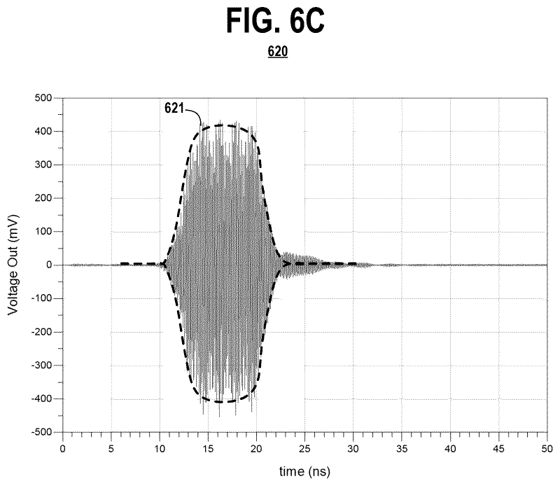

It is to be noted that under normal operation of the exemplary parametric gyrator circuits described herein (such as shown in FIG. 5), the amplitudes of the first and second pump control signals Pump_1 and Pump_2 would be the same, and selected to achieve a desired mode of operation for the given type of parametric coupling circuits (e.g., DC-SQUIDs, single Josephson junctions, etc.) that are implemented. However, the amplitudes of the first and second pump control signals Pump_1 and Pump_2 can be different for implementing other modes of operation. For example, as noted above, one of the pump control signals Pump_1 or Pump_2 can be configured to implement dynamic amplitude modulation (as shown and discuss in further detail below in conjunction with FIG. 6C).

In other embodiments, since the exemplary parametric gyrator circuits as described herein implement pump control signals Pump_1 or Pump_2 which allow phase and dynamic amplitude control of an output RF tone, a parametric gyrator circuit can be configured to generate shaped microwave control pulses for qubit readout or manipulation based on principles similar to IQ modulation. For example, the first control signal Pump_1 can be viewed as an in-phase (I) control signal, and the second control signal Pump_2 can be viewed as a quadrature-phase (Q) control signal. When the amplitudes of Pump_1 and Pump_2 are the same (to achieve the relevant matching for parametric gyrator circuit), the differential phase between Pump_1 (I phase) and Pump_2 (Q phase) can be offset to change the phase of the RF output. Additionally, for a given phase difference between Pump_1 and Pump_2, the ratio of the amplitudes (e.g., current) of Pump_1 and Pump_2 can be dynamically adjusted to generate a shaped microwave pulse. In this regard, by dynamic phase control and amplitude control of the control signals Pump_1 and Pump_2, a parametric gyrator circuit can be configured to generate shaped microwave control pulses for qubit readout or for driving a qubit to change the state of the qubit.

Next, FIGS. 6A, 6B, and 6C graphically illustrate simulated scattering parameters and operating modes of a superconducting parametric gyrator device, according to an exemplary embodiment. In particular, FIGS. 6A, 6B, and 6C graphically illustrate simulated scattering parameters and operating characteristics of a superconducting parametric gyrator device having a simulated circuit model based on the superconducting parametric gyrator device 500 of FIG. 5. For example, FIG. 6A illustrates a graph 600 which shows simulated scattering parameters of the simulated superconducting parametric gyrator device in terms of dB (y-axis) as a function of frequency in GHz (x-axis) over a range of 5.0 GHz to 10.0 GHz, wherein the parametric multipole bandpass filter 510 of FIG. 5 is modeled to have a signal band B_{Signal} with a center signal frequency of fₛ=7.25 GHz. In particular, FIG. 6A illustrates (i) a simulated transmission parameter S₂₁ which represents RF transmission parameter from the first I/O port P1 to the second I/O port, and (ii) a simulated reflection parameter S₁₁ which represent RF power reflection at the first I/O port P1. FIG. 6A illustrates that the transmission parameter S₂₁ is near unity in the signal passband B_{Signal} over a bandwidth BW of −500 MHz from ~7.0 GHz to ~7.5 GHz. In addition, FIG. 6A illustrates a low return loss Sn of about −40 dB over the bandwidth BW of the signal passband B_{Signal}.

Next, FIG. 6B illustrates a graph 610 which shows simulated phases for transmission parameters S₂₁ and S₁₂ of the simulated superconducting parametric gyrator device in terms of degree (y-axis) as a function of frequency in GHz (x-axis) over the signal passband B_{Signal} from 7.0 GHz to 7.5 GHz. FIG. 6B illustrates a legend with different characters that correspond to different values of Δ_{φ}=φ₁−φ₂, which represent differentials between the first and second phases of the first and second pump control signals Pump_1 and Pump_2. For purposes of illustration, FIG. 6B shows simulated phases of S₂₁ and S₁₂ over differential pump phase values of Δ_{φ}=45°, 90°, 135°, 180°, 225°, 270°, 315°, and 360°. FIG. 6B shows that the phases of S₂₁ (phases of RF signals output from the second I/O port P2) and the phases of S₁₂ (phases of RF signals that are output from the first I/O port P1) move in opposite directions (as indicated by the arrows), wherein S₁₂ has a positive phase change, and S₂₁ has a negative phase change, where the phase shifts of the RF signals are differential depending on the direction of the RF signal flow.

Next, FIG. 6C graphically illustrates a simulated waveform 620 of an amplitude modulated output signal which is generated by applying a simulated amplitude modulated Pump control signal to, e.g., the second parametric coupler 514-2, as schematically shown in FIG. 5. The simulated waveform 620 comprises an envelope 621 which represents a simulated amplitude modulating signal that is applied to the second control signal Pump_2 to generate the simulated waveform 620 of the amplitude modulated output signal, as shown in FIG. 6C.

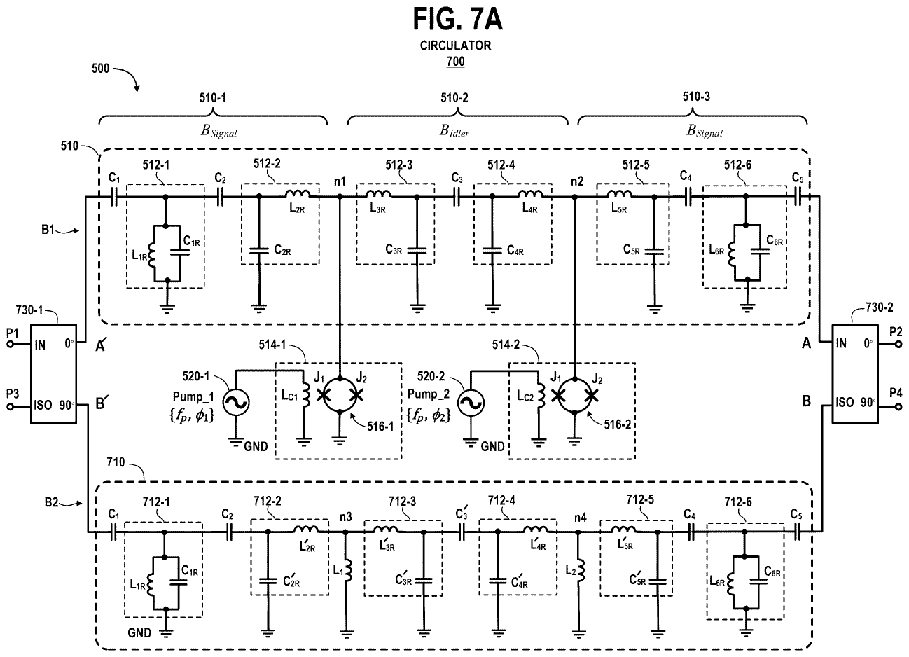

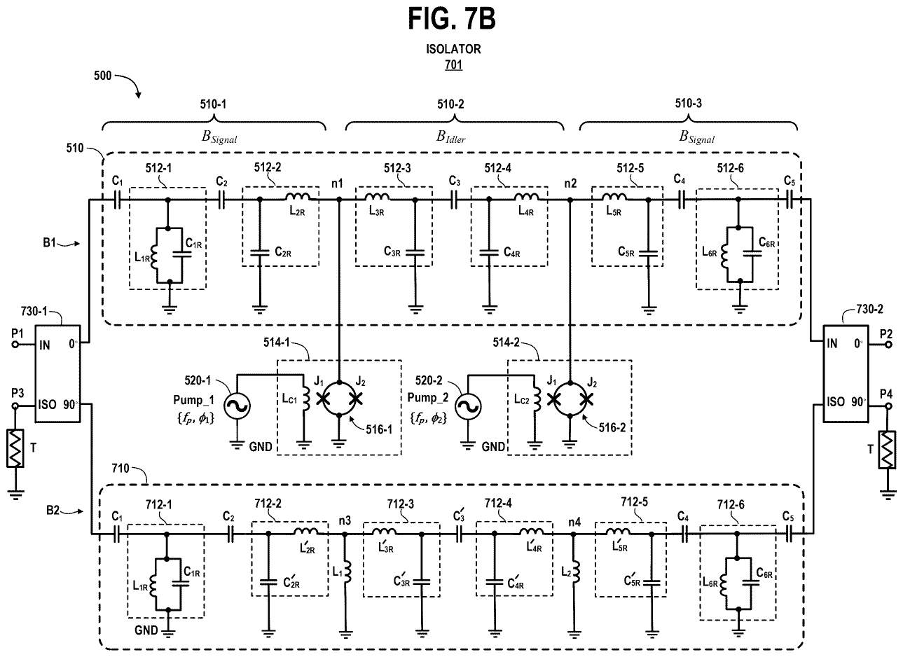

As noted above, superconducting parametric gyrator circuits, such as shown in FIG. 5, can be used to implement broadband superconducting isolator devices and superconducting circulator devices. For example, FIG. 7A schematically illustrates a superconducting circulator device which is implemented using a superconducting parametric gyrator, according to another exemplary embodiment of the disclosure. FIG. 7A schematically illustrates a superconducting circulator device 700 that has an architecture which is based on that of the superconducting circulator device 200 of FIG. 2A, and which implements a superconducting parametric gyrator circuit architecture based on that of the exemplary embodiment shown in FIG. 5.

In particular, the superconducting circulator device 700 comprises a first hybrid coupler 730-1, a second hybrid coupler 730-2, the superconducting parametric gyrator device 500 (of FIG. 5), and a multipole bandpass filter 710. The superconducting circulator device 700 is a 4-port device comprising a first port P1, a second port P2, a third port P3, and a fourth port P4. The superconducting parametric gyrator device 500 is disposed in a first branch B1 of the superconducting circulator device 700, while the multipole bandpass filter 710 is disposed in a second branch B2 of the superconducting circulator device 700, wherein the first and second branches B1 and B2 are coupled in parallel between the first hybrid coupler 730-1 and the second hybrid coupler 730-2. The superconducting circulator device 700 of FIG. 7A can be represented by the 4-port circulator symbol 200A shown in FIG. 2A, and operates in a similar manner with regard to routing RF signals between ports, as discussed above.

In some embodiments, the first and second hybrid couplers 730-1 and 730-2 are quadrature (90°) hybrid couplers, which operate as power dividers and power combiners, as discussed above. As schematically shown in FIG. 7A, the parametric multipole bandpass filter 510 (of the superconducting parametric gyrator device 500) is coupled to and between the 0° port of the first hybrid coupler 730-1 and the IN port of the second hybrid coupler 730-2, while the multipole bandpass filter 710 is coupled to and between the 90° port of the first hybrid coupler 730-1 and the ISO port of the second hybrid coupler 730-2.

As discussed above, the superconducting parametric gyrator device 500 implements the parametric multipole bandpass filter 510 to produce gyration by implementing the first and second parametric couplers 514-1 and 514-2 to couple the linear sections (e.g., the first, second, and third filter portions 510-1, 510-2, and 510-3) of the parametric multipole bandpass filter 510, and by driving the first and second parametric couplers 514-1 and 514-2 with respective first and second pump control signals Pump_1 and Pump_2, which have the same frequency fₚ, but different first and second phases φ₁ and φ₂ to thereby perform parametric frequency mixing (e.g., three-wave parametric frequency mixing or four-wave parametric frequency mixing) to achieve non-reciprocal phase shifting (gyration) of an output signal, depending on the direction of RF signal flow through the superconducting parametric gyrator device 500, the details of which will not be repeated.

As schematically illustrated in FIG. 7A, in some embodiments, the multipole bandpass filter 710 implements a 6-pole bandpass filter network architecture which is similar to that of the parametric multipole bandpass filter 510, but the multipole bandpass filter 710 utilizes linear couplers in place of the first and second parametric couplers 514-1 and 514-2 (of the parametric multipole bandpass filter 510) and comprises a “single band” bandpass filter network which, for example, does not implement the idler passband B_{Idler} of the parametric multipole bandpass filter 510, and is configured to provide one signal passband having a center frequency fₛ which corresponds to the center frequency fₛ of the signal passband B_{Signal} of the first and third filter sections 510-1 and 510-3 of the parametric multipole bandpass filter 510.

It is to be appreciated that the exemplary architecture of the superconducting circulator device 700 provides a “reflectionless” superconducting circulator device, wherein the reflection parameters S₁₁, S₂₂, S₃₃, and S₄₄ of the superconducting circulator device 700 are significantly suppressed both in-band and out-of-band of the given bandwidth of operation (e.g., B_{Signal}) of the superconducting circulator device 700. Moreover, in the exemplary architecture of the superconducting circulator device 700, the multipole bandpass filter 710 is configured to have a group delay in the second branch B2 which corresponds to (e.g., matches) the group delay of the parametric multipole bandpass filter 510 of the superconducting parametric gyrator device 500 in the first branch B1.

As schematically illustrated in FIG. 7A, the multipole bandpass filter 710 comprises an immittance inverting multipole bandpass filter network comprising six (6) resonator circuits and seven (7) coupling circuits. In particular, the multipole bandpass filter 710 comprises a first resonator circuit 712-1, a second resonator circuit 712-2, a third resonator circuit 712-3, a fourth resonator circuit 712-4, a fifth resonator circuit 712-5, and a sixth resonator circuit 712-6 (collectively, resonator circuits 712). The coupling circuits are all linear couplers implemented by coupling capacitors including a first coupling capacitor C₁, a second coupling capacitor C₂, a third coupling capacitor

$${C}_{3}^{′} ,$$

a fourth coupling capacitor C₄, and a fifth coupling capacitor C₅. In addition, the coupling circuits comprises two linear couplers implemented by a first coupling inductor L₁ and a second coupling inductor L₂, wherein the first coupling inductor L₁ is coupled to and between a node n3 (of the multipole bandpass filter 710) and ground GND, and wherein the second coupling inductor L₂ is coupled to and between a node n4 (of the multipole bandpass filter 710) and ground GND.

The first resonator circuit 712-1 comprises an inductor L_{1R} and a capacitor C_{1R}, the second resonator circuit 712-2 comprises an inductor

$${L}_{2 R}^{′}$$

and a capacitor

$${C}_{2 R}^{′} ,$$

the third resonator circuit 712-3 comprises an inductor

$${L}_{3 R}^{′}$$

and a capacitor

$${C}_{3 R}^{′} ,$$

the fourth resonator circuit 712-4 comprises an inductor

$${L}_{4 R}^{′}$$

and a capacitor

$${C}_{4 R}^{′} ,$$

the fifth resonator circuit 712-5 comprises an inductor

$${L}_{5 R}^{′}$$

and a capacitor

$${C}_{5 R}^{′} ,$$

and the sixth resonator circuit 712-6 comprises an inductor L_{6R} and a capacitor C_{6R}. In addition, the multipole bandpass filter 710 utilizes capacitive π-networks to implement linear capacitive coupling, wherein first coupling capacitor C₁ is configured to linearly couple the first I/O port of the multipole bandpass filter 710 (which is coupled to the 90° port of the first hybrid coupler 730-1) and the first resonator circuit 712-1, the second coupling capacitor C₂ is configured to linearly couple the first resonator circuit 712-1 and the second resonator circuit 712-2, the third coupling capacitor

$${C}_{3}^{′}$$

is configured to linearly couple the third resonator circuit 712-3 and the fourth resonator circuit 712-4, the fourth coupling capacitor C₄ is configured to linearly couple the fifth resonator circuit 712-5 and the sixth resonator circuit 712-6, and the fifth coupling capacitor C₅ is configured to linearly couple the sixth resonator circuit 712-6 and the second I/O port of the multipole bandpass filter 710 (which is coupled to the ISO port of the second hybrid coupler 730-2).

Moreover, FIG. 7A schematically illustrates an exemplary embodiment in which the multipole bandpass filter 710 implements a first inductive T network to linearly couple the second and third resonator circuits 712-2 and 712-3, and a second inductive T network to linearly couple the fourth and fifth resonator circuits 712-4 and 712-5. In particular, the first inductive T network is comprised of the inductors

$${L}_{2 R}^{′} and {L}_{3 R}^{′}$$

(of the second and third resonator circuits 712-2 and 712-3), and the first coupling inductor L₁, which are commonly coupled to the node n3. In this configuration, the inductors

$${L}_{2 R}^{′} and {L}_{3 R}^{′}$$

are essentially shunted to ground GND through the first coupling inductor L₁, to thereby provide a linear mutual coupling between the second and third resonator circuits 712-2 and 712-3. In addition, the second inductive T network is comprised of the inductors

$${L}_{4 R}^{′} and {L}_{5 R}^{′}$$

(of the fourth and fifth resonator circuits 712-4 and 712-5), and the second coupling inductor L₂, which are commonly coupled to the node n4. In this configuration, the inductors

$${L}_{4 R}^{′} and {L}_{5 R}^{′}$$

are essentially shunted to ground GND through the second coupling inductor L₂, to thereby provide a linear mutual coupling between the fourth and fifth resonator circuits 712-4 and 712-5.

FIG. 7A illustrates an exemplary circuit configuration where the multipole bandpass filter 710 has a circuit architecture and layout which corresponds to that of the parametric multipole bandpass filter 510. However, the multipole bandpass filter 710 implements the first and second coupling inductors L₁ and L₂ (and T network configuration) to provide (i) a linear mutual inductive coupling between the second and third resonator circuits 712-2 and 712-3 and (ii) a linear mutual inductive coupling between the fourth and fifth resonator circuits 712-4 and 712-5, which are used in place of the first and second parametric couplers 514-1 and 514-2 of the of the parametric multipole bandpass filter 510 for parametrically coupling such resonator circuits.

Moreover, as schematically illustrated in FIG. 7A, in some embodiments, the coupling capacitors C₁, C₂, C₄, and C₄ of the parametric multipole bandpass filter 510 and the multipole bandpass filter 710 are nominally identical (e.g., in terms of capacitance values). In addition, in some embodiments, the first resonator circuits 512-1 and 712-1 are nominally identical in terms of, e.g., the inductance and capacitance values of the inductor L_{1R} and capacitor C_{1R} components, and the sixth resonator circuits 512-6 and 712-6 are nominally identical in terms of, e.g., the inductance and capacitance values of the inductor L_{6R} and capacitor C_{6R} components. However, the capacitance value of the coupling capacitor

$${C}_{3}^{′}$$

and the capacitance and inductance values of the capacitor and inductor elements of the second, third, fourth, and fifth resonator circuits 712-2, 712-3, 712-4, and 712-5 of the multipole bandpass filter 710, are different from those of the corresponding components, i.e., the coupling capacitor C₃ and the capacitor and inductor elements of the second, third, fourth, and fifth resonator circuits 512-2, 512-3, 512-4, and 512-5, of the parametric multipole bandpass filter 510.

From an engineering design standpoint, the implementation of the multipole bandpass filter 710 having a circuit architecture and layout which corresponds to that of the parametric multipole bandpass filter 510 facilitates the circuit design and layout of the superconducting circulator device 700, for reasons understood by those of ordinary skill in the art. For example, for purposes of circuit layout and design of a superconducting parametric gyrator, it may be highly desirable to engineer the parametric multipole bandpass filter (in the first branch B1) and the linear multipole bandpass filter (in the second branch) to be as similar as possible in terms of layout and component values, so that electrical parameters of the parametric and linear bandpass filters can be more easily tailored to achieve desired circuit performance, impedance matching, and to more easily achieve a matching group delay between signals that propagate in the first and second branches B1 and B2 of the superconducting parametric gyrator circuit. Indeed, by implementing parametric (non-linear) and linear bandpass filters that are similar in circuit layout, the non-linear bandpass filter and/or linear bandpass filter can be more easily tailored in optimization so that the group delay or phase slope (i.e., change of phase as a function of frequency) in both branches B1 and B2 is matched.

In other embodiments, however, the parametric (non-linear) multipole bandpass filter (in the first branch B1) and the linear multipole bandpass filter (in the second branch B2) of a superconducting parametric gyrator can be different in terms of circuit configuration and layout, as may be desired for a given application. For example, in an exemplary non-limiting embodiment, the linear multipole bandpass filter 710 shown in FIG. 7A can have a 6-pole bandpass filter network comprising six resonator circuits, wherein each resonator circuit comprises a parallel LC circuit, and wherein all linear couplers are implemented using, e.g., coupling capacitors. Again, as noted above, while exemplary embodiments of superconducting parametric gyrator circuits, and superconducting circulator and isolator devices are illustrated herein as implementing immittance inverting multipole bandpass filter networks, in other embodiments, superconducting parametric gyrator circuits, and superconducting circulator and isolator devices can be implemented using other bandpass filter network topologies which are suitable for the intended applications as described herein.

The superconducting circulator device 700 comprises a 4-port superconducting circulator device, whereby in operation, an RF signal entering port P₁ is routed to port P₂ (P₁→P₂), an RF signal entering port P₂ is routed to port P₃ (P₂→P₃), an RF signal entering port P₃ is routed to port P₄ (P₃→P₄), and an RF signal entering port P₄ is routed to port P₁ (P₄→P₁), wherein the routing of an RF signal from one port to another port of the superconducting circulator device 700 is performed with high isolation from the other ports of the superconducting circulator device 700. In some embodiments, as noted above, the first and second branches B1 and B2 are configured to have a matching phase slope (or matching group delay), and the linear multipole bandpass filter 710 is designed to introduce a constant phase offset (e.g. 90 degrees) in the second branch B2, in a desired frequency band of interest, to thereby achieve a constant phase offset between the first and second branches B1 and B2 which is needed to properly implement the first and second hybrid couplers 730-1 and 730-2.

By way of example, assuming the linear multipole bandpass filter 710 introduces a constant 90-degree phase shift in the second branch B2, the superconducting circulator device 700 operated to achieve non-reciprocal signal routing of (P₁→P₂), (P₂→P₃), (P₃→P₄), and (P₄→P₁), as follows. For ease of discussion, as illustrated in FIG. 7, labels A and A′ denote signal phases at the input and output nodes of the first branch B1, while labels B and B′ denote signal phases at the input and output nodes second branch B2. In the following discussion, the phase offset of the linear multipole bandpass filter 710 in branch B2 (or simply, linear phase offset in branch B2) is denoted θ. Moreover, in the following discussion, for illustrative purposes, it is assumed that Δ_{φ}=φ₁−φ₂ is set to −90°.

To achieve non-reciprocal signal routing from the first port P1 to the second port P2 (P₁→P₂), the signal phases A and B should have a phase difference of A ~B=90°. In this regard, the signal phase A will be Δ_{φ} and the signal phase B will be −90°−θ, where θ is the linear phase offset in branch B2 (where A−B=Δ_{φ}−(−90°−θ)=+90°). This results in Δ_{φ}=θ. In this instance, after passing through the second hybrid coupler 730-2, the signal phases A and B are in phase and are constructively combined at the second port P2, while the signal phases A and B are destructively combined and canceled at the fourth port P4.

Next, to achieve non-reciprocal signal routing from the second port P2 to the third P3 of (P₂→P₃), the signal phases A′ and B′ should have a phase difference of A′−B′=−90°. In this regard, when Δ_{φ}=φ₁−φ₂ is set to θ, the signal phase A′=−Δ_{φ} and the signal phase B′=−90+θ where A′−B′=−4+90−θ−90°). The equations, when combined for non-reciprocal transmission show that in this case, the linear phase offset in branch B2 must be θ=90 degrees. In this instance, after passing through the first hybrid coupler 730-1, the signal phases A′ and B′ are in phase and are constructively combined at the third port P3, while the signal phases A′ and B′ are destructively combined and canceled at the first port P1.

Furthermore, to achieve non-reciprocal signal routing from the third port P3 to the fourth port P4 (P₃→P₄), the signal phases A and B should have a phase difference of A −B=−90°. In this regard, the signal phase A=−90°+Δ_{φ}, and the signal phase B will be θ (where A −B=−90°+Δ_{φ}−θ=−90°). In this instance, after passing through the second hybrid coupler 730-2, the signal phases A and B are in phase and are constructively combined at the fourth port P4, while the signal phases A and B are destructively combined and canceled at the second port P2.

Finally, to achieve non-reciprocal signal routing from the fourth port P4 to the first port P1 (P₄→P1), the signal phases A′ and B′ should have a phase difference of A′−B′=+90°. In this regard, the signal phase A′=−90 −Δ_{φ}, and the signal phase B′ will be θ (where A′−B′=−90 −Δ_{φ}−θ=+90°). In this instance, after passing through the first hybrid coupler 730-1, the signal phases A′ and B′ are in phase and are constructively combined at the first port P1, while the signal phases A′ and B′ are destructively combined and canceled at the third port P3.

It is to be noted that the above signal routing examples illustrate that non-reciprocal signal routing for all signal paths (P₁→P₂), (P₂→P₃), (P₃→P₄), and (P₄→P₁) can be achieved by setting the phase difference Δ_{φ}, value between Pump_1 and Pump_2 to be Δ_{φ}=φ₁−φ₂=θ where, as noted above, θ denotes the linear phase offset in branch B2 (e.g., θ=90°). It is to be noted that by configuring both branches B1 and B2 of the superconducting circulator device 700 to have the same group delay, non-reciprocal signal routing for all signal paths can be achieved for different values Δ_{φ}=φ₁−φ₂=θ. In this regard, if a plurality of input signals S_{IN1}, S_{IN2}, S_{IN3}, S_{IN4} are concurrently applied to the respective ports P1, P2, P3, and P4, the superconducting circulator device 700 would concurrently route the signals S_{IN1}, S_{IN2}, S_{IN3}, S_{IN4} to the respective ports P2, P3, P4, and P1 under that same phase difference Δ_{φ} setting.

Next, FIG. 7B schematically illustrates a superconducting isolator device which is implemented using a superconducting parametric gyrator, according to another exemplary embodiment of the disclosure. In particular, FIG. 7B schematically illustrates a superconducting isolator device 701 which has the same circuit architecture as the superconducting circulator device 700 of FIG. 7A, except that each of two ports, e.g., the third and fourth ports P3 and P4, are terminated with a matched termination T. It is to be noted that the superconducting isolator device 701 has a circuit architecture which is based on the general architecture of the superconducting isolator device 201 (FIG. 2B) which correspond to the 2-port isolator symbol 201A (FIG. 2B), wherein in operation, an RF signal entering port P₁ is routed to port P₂ (P₁→P₂), but wherein an RF signal entering port P₂ is routed to port P₃ (P₂→P₃) where the RF signal is terminated with high isolation such that the transmission parameter S₁₂ is significantly suppressed.

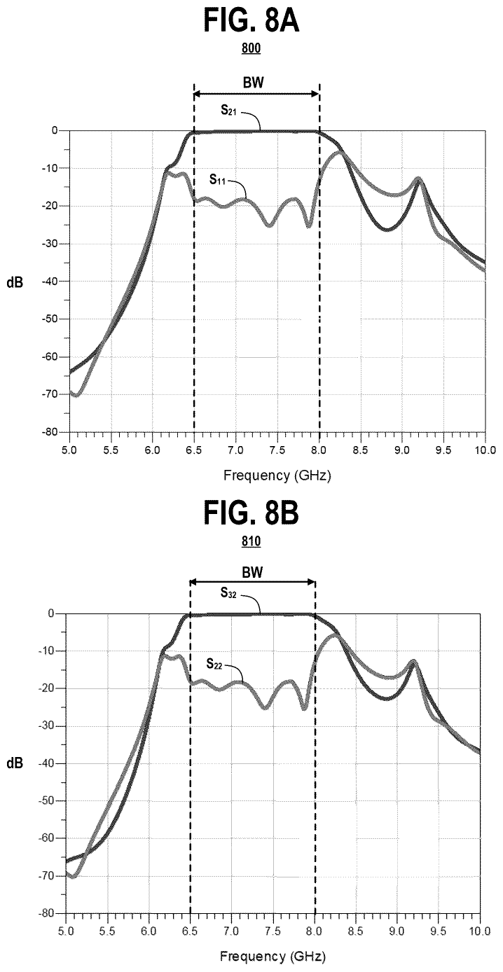

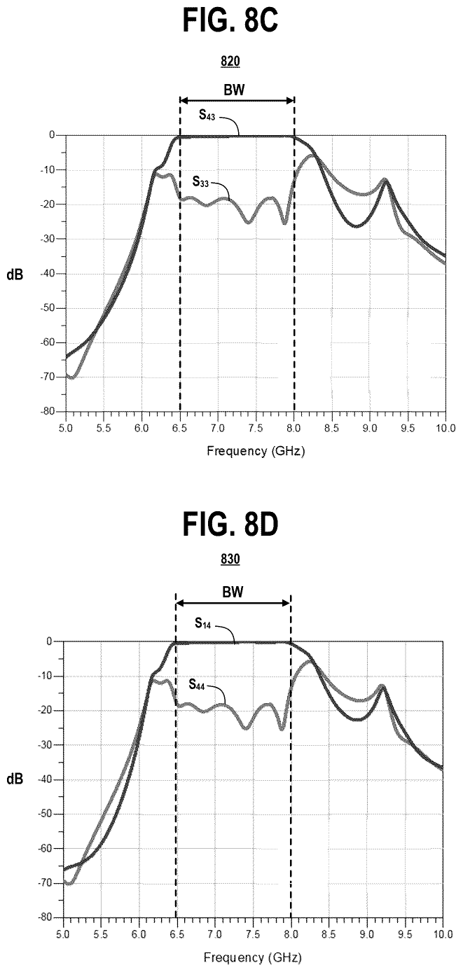

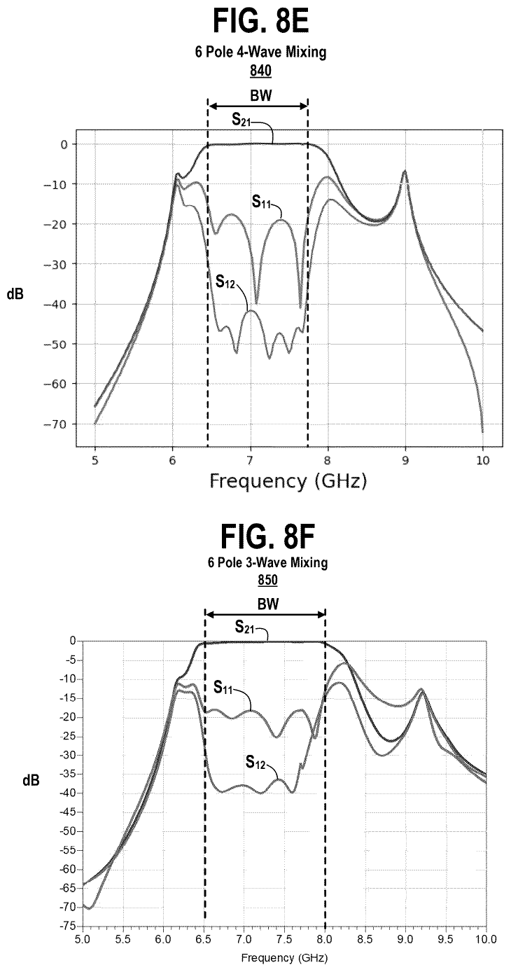

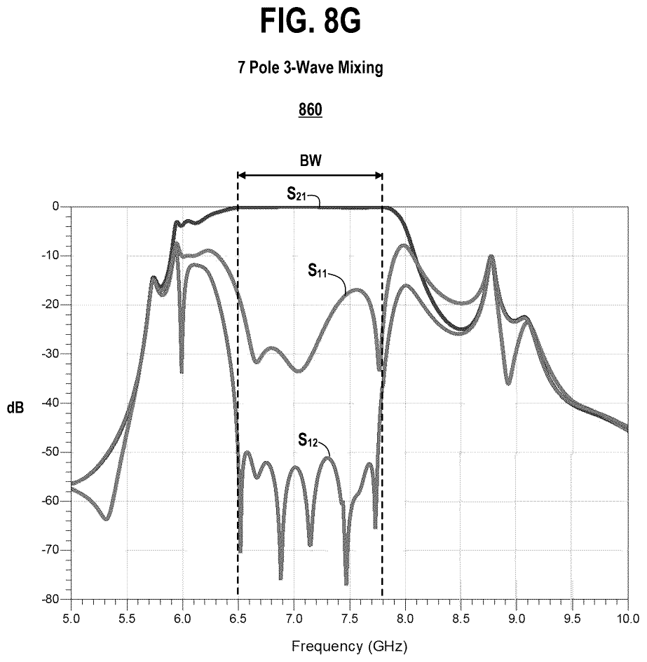

Next, FIGS. 8A, 8B, 8C, and 8D graphically illustrate simulated scattering parameters of a superconducting circulator device, according to an exemplary embodiment of the disclosure. In particular, FIGS. 8A-8D graphically illustrate simulated scattering parameters of a superconducting circulator device having a simulated circuit model based on the superconducting circulator device 700 of FIG. 7A. For example, FIG. 8A illustrates a graph 800 which shows simulated scattering parameters of the simulated circuit model of the superconducting circulator device 700 in terms of dB (y-axis) as a function of frequency in GHz (x-axis) over a frequency range of 5.0 GHz to 10.0 GHz, where the parametric multipole bandpass filter 510 and the linear multipole bandpass filter 710 are modeled to have a signal band B_{Signal} with a center signal frequency of fₛ=7.25 GHz. In particular, FIG. 8A illustrates (i) a simulated transmission parameter S₂₁ which represents RF power transmission from the first port P1 to the second port P2, and (ii) a simulated reflection parameter S₁₁ which represents RF power reflection at the first port P1. FIG. 8A illustrates that the transmission parameter S₂₁ is near unity in the signal passband B_{Signal} over a bandwidth BW of ~1.5 GHz from ~6.5 GHz to ~8.0 GHz. In addition, FIG. 8A illustrates an in-band rejection Sn of about ~20 dB or better over the bandwidth BW of the signal passband B_{Signal}.

Next, FIG. 8B illustrates a graph 810 which shows simulated scattering parameters of the simulated circuit model of the superconducting circulator device 700 including (i) a simulated transmission parameter S₃₂ which represents RF power transmission from the second port P2 to the third port P3, and (ii) a simulated rejection S₂₂ which represents RF power reflection at the second P2. FIG. 8B illustrates that the transmission parameter S₃₂ is near unity in the signal passband B_{Signal} over the bandwidth BW (~1.5 GHz) from ~6.5 GHz to ~8.0 GHz. In addition, FIG. 8B illustrates an in-band rejection S₂₂ of about −20 dB or better over the bandwidth BW of the signal passband B_{Signal}.

Next, FIG. 8C illustrates a graph 820 which shows simulated scattering parameters of the simulated circuit model of the superconducting circulator device 700 including (i) a simulated transmission parameter S₄₃ which represents RF power transmission from the third port P4 to the fourth port P4, and (ii) a simulated reflection parameter S₃₃ which represents RF power reflection at the third port P3. FIG. 8C illustrates that the transmission parameter S₄₂ is near unity in the signal passband B_{Signal} over the bandwidth BW (~1.5 GHz) from ~6.5 GHz to ~8.0 GHz. In addition, FIG. 8C illustrates an in-band rejection S₃₃ of about −20 dB or better over the bandwidth BW of the signal passband B_{Signal}.

Next, FIG. 8D illustrates a graph 830 which shows simulated scattering parameters of the simulated circuit model of the superconducting circulator device 700 including (i) a simulated transmission parameter S₁₄ which represents RF power transmission from the fourth port P4 to the first port P1, and (ii) a simulated reflection parameter S₄₄ which represents RF power reflection at the fourth port P4. FIG. 8D illustrates that the transmission parameter S₁₄ is near unity in the signal passband B_{Signal} over the bandwidth BW (~1.5 GHz) from ~6.5 GHz to ~8.0 GHz. In addition, FIG. 8D illustrates an in-band rejection S₄₄ of about −20 dB or better over the bandwidth BW of the signal passband B_{Signal}.

It is to be noted that FIGS. 8A, 8B, 8C, and 8D further illustrate that the simulated circuit model of the superconducting circulator device 700 of FIG. 7A is an implementation of a “reflectionless” 4-port superconducting circulator device, wherein FIGS. 8A-8D shows that the simulated reflection parameters S₁₁, S₂₂, S₃₃, and S₄₄ are suppressed outside the operating bandwidth BW (out of band) of the superconducting circulator device 700. As noted above, the reflectionless implementation of the superconducting circulator device 700 is achieved at least in part by utilizing the linear multipole bandpass filter 710 in parallel with the parametric multipole bandpass filter 510.

Next, FIGS. 8E and 8F graphically illustrate simulated scattering parameters of a superconducting isolator device, according to an exemplary embodiment of the disclosure. In particular, FIGS. 8E and 8F graphically illustrate simulated scattering parameters of a superconducting isolator device having a simulated circuit model based on the superconducting isolator device 701 of FIG. 7B. In particular, FIG. 8E illustrates a graph 840 which shows simulated scattering parameters of the simulated circuit model of the superconducting isolator device 701 utilizing four-wave mixing in terms of dB (y-axis) as a function of frequency in GHz (x-axis) over a frequency range of 5.0 GHz to 10.0 GHz, where the parametric multipole bandpass filter 510 and the linear multipole bandpass filter 710 are modeled to have a signal band B_{Signal} with a center signal frequency of fₛ=7.25 GHz, and where the parametric multipole bandpass filter 510 is configured to perform 4-wave parametric frequency mixing.

In particular, FIG. 8E illustrates (i) a simulated transmission parameter S₂₁ which represents RF power transmission from the first port P1 to the second port P2, (ii) a simulated reflection parameter S₁₁ which represents RF power reflection at the first port P1, and (iii) a simulated transmission parameter S₁₂ which represents RF signal isolation of the first port P1 from the second port P2. FIG. 8E illustrates that the transmission parameter S₂₁ is near unity in the signal passband B_{Signal} over a bandwidth BW of ~1.25 GHz from ~6.5 GHz to ~7.75 GHz, and that the isolation S₁₂ is about −40 dB or better over the bandwidth BW of the signal passband B_{Signal}. In addition, FIG. 8E illustrates that the in-band rejection S₁₁ is about −20 dB or better over the bandwidth BW of the signal passband B_{Signal}, and that reflection parameter S₁₁ the suppressed outside the operating bandwidth BW (out of band) of the superconducting isolator device 701 thereby providing a reflectionless 2-port superconducting isolator device.

Next, FIG. 8F illustrates a graph 850 which shows simulated scattering parameters of the simulated circuit model of the superconducting isolator device 701 utilizing three-wave mixing in terms of dB (y-axis) as a function of frequency in GHz (x-axis) over a frequency range of 5.0 GHz to 10.0 GHz, where the parametric multipole bandpass filter 510 and the linear multipole bandpass filter 710 are modeled to have a signal band B_{Signal} with a center signal frequency of fₛ=7.25 GHz, and where the parametric multipole bandpass filter 510 is configured to perform 3-wave parametric frequency mixing.

In particular, FIG. 8F illustrates (i) a simulated transmission parameter S₂₁ which represents RF power transmission from the first port P1 to the second port P2, (ii) a simulated reflection parameter S₁₁ which represents RF power reflection at the first port P1, and (iii) a simulated transmission parameter S₁₂ which represents RF signal isolation of the first port P1 from the second port P2. FIG. 8F illustrates that the transmission parameter S₂₁ is near unity in the signal passband B_{Signal} over a bandwidth BW of ~1.50 GHz from ~6.5 GHz to ~8.0 GHz, and that the isolation S₁₂ is about −35 dB or better over the bandwidth BW of the signal passband B_{Signal}. In addition, FIG. 8F illustrates that the in-band rejection is about −20 dB or better over the bandwidth BW of the signal passband B_{Signal}, and that the reflection parameter S₁₁ is suppressed outside the operating bandwidth BW (out of band) of the superconducting isolator device 701 thereby providing a reflectionless 2-port superconducting isolator device.

FIG. 8G graphically illustrates simulated scattering parameters of a superconducting isolator device, according to another embodiment of the disclosure. In particular, FIG. 8G illustrates a graph 860 which shows simulated scattering parameters of a simulated circuit model of a three-wave mixing superconducting isolator device in terms of dB (y-axis) as a function of frequency in GHz (x-axis) over a frequency range of 5.0 GHz to 10.0 GHz, where the simulated circuit model of the superconducting isolator device implements 7-pole three-wave mixing parametric and linear bandpass filters, which are modeled to have a signal band B_{Signal} with a center signal frequency of fₛ=7.25 GHz, and where the simulated 7-pole parametric bandpass filter is configured to perform 3-wave parametric frequency mixing. In particular, as compared to the exemplary parametric multipole bandpass filter 510 of FIG. 7B with 2-poles (third and fourth resonator circuits 512-3 and 512-4) in the second filter section 510-2 (idler section), the simulated 7-pole parametric bandpass filter circuit was modeled to have 3-poles in the second filter section (idler section), e.g., with an additional parallel LC resonator disposed between the second and third resonators 512-3 and 512-4, and linearly coupled to the second and third resonators 512-3 and 512-4 with coupling capacitors.

With regard to the simulated circuit model of the superconducting isolator device having the 7-pole parametric and linear bandpass filters, FIG. 8G illustrates (i) a simulated transmission parameter S₂₁ which represents RF power transmission from the first port P1 to the second port P2, (ii) a simulated reflection parameter S₁₁ which represents RF power reflection at the first port P1, and (iii) a simulated transmission parameter S₁₂ which represents RF signal isolation of the first port P1 from the second port P2. FIG. 8G illustrates that the transmission parameter S₂₁ is near unity in the signal passband B_{Signal} over a bandwidth BW of ~1.25 GHz from ~6.5 GHz to ~7.75 GHz, and that the S₁₂ isolation is better than 50 dB over the bandwidth BW of the signal passband B_{Signal}. In addition, FIG. 8G illustrates that the in-band rejection Sn is about ~20 dB or better over the bandwidth BW of the signal passband B_{Signal}, and that the reflection parameter Sn is suppressed outside the operating bandwidth BW (out of band) of the 7-pole superconducting isolation device thereby providing a reflectionless 2-port superconducting isolator device.

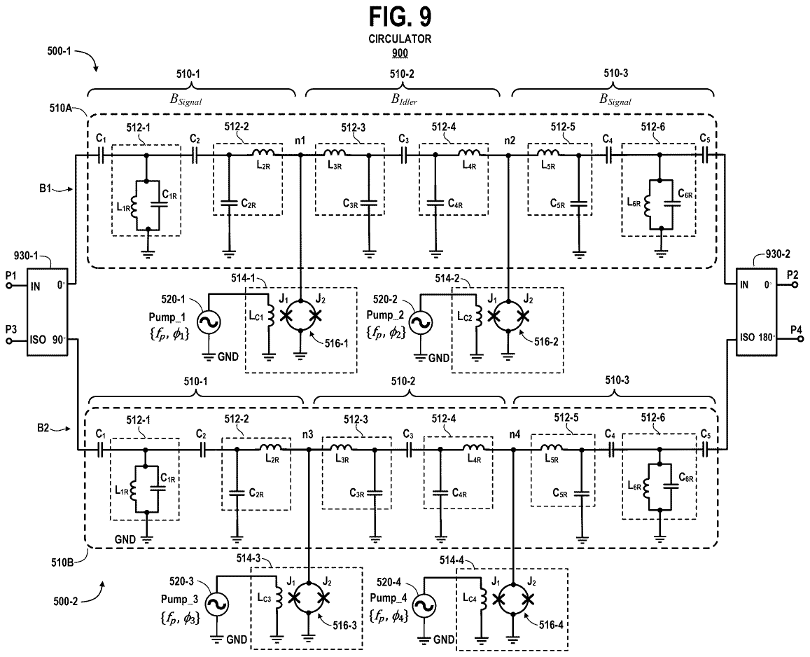

FIG. 9 schematically illustrates a superconducting circulator device which is implemented using two superconducting parametric gyrators, according to another exemplary embodiment of the disclosure. FIG. 9 schematically illustrates a superconducting circulator device 900 that has an architecture which is based on that of the superconducting circulator device 202 of FIG. 2C. In particular, superconducting circulator device 900 comprises a first port P1, a second port P2, a third port P3, a fourth port P4, a first hybrid coupler 930-1, a second hybrid coupler 930-2, a first superconducting parametric gyrator 500-1, and a second superconducting parametric gyrator 500-2. The first superconducting parametric gyrator 500-1 is disposed in a first branch B1 of the superconducting circulator device 900, while the second superconducting parametric gyrator 500-2 is disposed in a second branch B2 of the superconducting circulator device 900, wherein the first and second branches B1 and B2 are coupled in parallel between the first hybrid coupler 930-1 and the second hybrid coupler 930-2. The superconducting circulator device 900 can be represented by the 4-port circulator symbol 200A shown in FIG. 2A, and operates in a similar manner with regard to routing RF signals between ports, as discussed above.

The first superconducting parametric gyrator 500-1 and the second superconducting parametric gyrator 500-2 are nominally identical circuits in terms of circuit architecture, circuit layout, and modes of operation. FIG. 9 illustrates an exemplary embodiment in which each of the first superconducting parametric gyrator 500-1 and the second superconducting parametric gyrator 500-2 comprise an instance of the superconducting parametric gyrator device 500 of FIGS. 7A and 7B, the details of which will not be repeated. For example, the first and second superconducting parametric gyrators 500-1 and 500-2 comprise respective parametric multipole bandpass filters 510A and 510B which are nominally identical instances of the parametric multipole bandpass filter 510 shown in FIGS. 7A and 7B.

In the exemplary superconducting circular device configuration of FIG. 9, the first and hybrid coupler 930-1 is a quadrature (90°) hybrid coupler, and the second hybrid coupler 930-2 comprises a 1800 hybrid coupler. The parametric multipole bandpass filter 510A of the first superconducting parametric gyrator 500-1 is coupled to and between the 0° port of the first hybrid coupler 930-1 and the IN port of the second hybrid coupler 930-2, while the parametric multipole bandpass filter 510B of the second superconducting parametric gyrator 500-2 is coupled to and between the 90° port of the first hybrid coupler 930-1 and the ISO port of the second hybrid coupler 930-2.

The second superconducting parametric gyrator 500-2 is operated by a third control signal Pump_3 and a fourth control signal Pump_4, which are generated by a third control signal generator 520-3 and a fourth control signal generator 520-4, respectively. The third and fourth control signals Pump_3 and Pump_4 have the same frequency fₚ as the first and second control signals Pump_1 and Pump_2. The third control signal Pump_3 has a third phase φ₃, and the fourth control signal Pump_4 has a fourth phase φ₄, which differs from the third phase φ₃.

In addition, the second superconducting parametric gyrator 500-2 comprises a third parametric coupler 514-3 which is coupled to a node n3 of the parametric multipole bandpass filter 510B, and a fourth parametric coupler 514-4 which is coupled to a node n4 of the parametric multipole bandpass filter 510B. The third parametric coupler 514-3 comprises a third DC-SQUID 516-3 and a third coupling inductor L_{C3} disposed adjacent to a superconducting loop of the third DC-SQUID 516-3. The fourth parametric coupler 514-4 comprises a fourth DC-SQUID 516-4 and a fourth coupling inductor L_{C4} disposed adjacent to a superconducting loop of the fourth DC-SQUID 516-4. The third and fourth parametric couplers 514-3 and 514-4 of the parametric multipole bandpass filter 510B, are nominally identical in circuit architecture and operation as the first and second parametric couplers 514-1 and 514-2 of the parametric multipole bandpass filter 510A. However, the superconducting circulator device 900 provides a circuit architecture which enables fine tuning of the different phases and/or the amplitudes of the control signals Pump_1, Pump_2, Pump_3, and/or Pump_4 to compensate for phase imbalances and/or amplitude imbalances that are introduced in the signal branches B1 and/or B2, or introduced by the first and second hybrid couplers 930-1 and 930-2.

In addition, the superconducting circulator device 900 provides a circuit architecture which allows the same superconducting parametric gyrator circuit to be used in both branches B1 and B2 to reduce the overhead in designing a matching linear circuit and/or ensure that RF signals propagating in the first and second branches B1 and B2 have the same or similar group delay. Moreover, as with other exemplary embodiments discussed above, the superconducting circulator device 900 can be used to implement a 2-port superconducting isolator device by terminating each of two ports, e.g., the third and fourth ports P3 and P3, with a matched termination T.

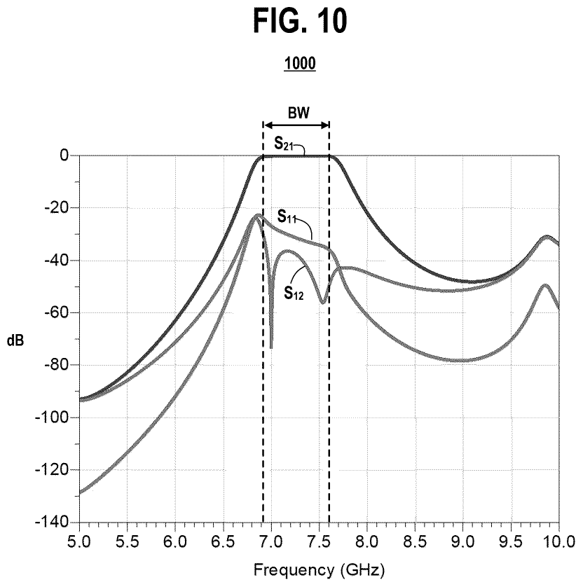

Next, FIG. 10 graphically illustrates simulated scattering parameters of a superconducting isolator device, according to another exemplary embodiment of the disclosure. In particular, FIG. 10 graphically illustrate simulated scattering parameters of a superconducting isolator device having a simulated circuit model based on the superconducting circulator device 900 of FIG. 9 which is implemented as a superconducting isolator with the third port P3 and the fourth port P4 terminated with matched loads to ground GND. FIG. 10 illustrates a graph 1000 which shows simulated scattering parameters of the simulated circuit model of the superconducting isolate device in terms of dB (y-axis) as a function of frequency in GHz (x-axis) over a frequency range of 5.0 GHz to 10.0 GHz, where the parametric multipole bandpass filters 510A and 510B (6-pole filters) are modeled to have a signal band B_{Signal} with a center signal frequency of fₛ=7.25 GHz.

In particular, FIG. 10 illustrates (i) a simulated transmission parameter S₂₁ which represents normalized RF transmission parameter from the first port P1 to the second port P2, (ii) a simulated reflection parameter S₁₁ which represents normalized RF power reflection at the first port P1, and (iii) a simulated transmission parameter S₁₂ which represents normalized RF signal isolation of the first port P1 from the second port P2. FIG. 10 illustrates that the transmission parameter S₂₁ is near unity in the signal passband B_{Signal} over a bandwidth BW of ~600 MHz from ~6.9 GHz to ~7.6 GHz, and that the isolation S₁₂ is about 40 dB or better over the bandwidth BW of the signal passband B_{Signal}. In addition, FIG. 10 illustrates that the in-band rejection Sn is better than −20 dB over the bandwidth BW of the signal passband B_{Signal}, and that the simulated reflection parameter S₁₁ is suppressed outside the operating bandwidth BW (out of band) of the superconducting isolator device, thereby providing a reflectionless superconducting isolator device.

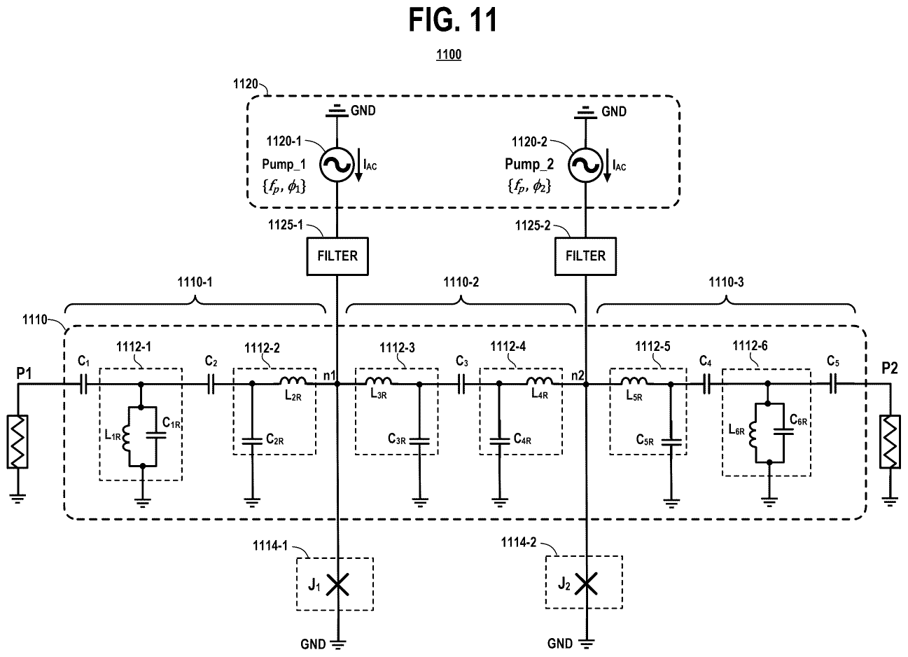

Next, FIG. 11 schematically illustrates a superconducting parametric gyrator device which comprises a parametric multipole bandpass filter circuit, according to another exemplary embodiment of the disclosure. FIG. 11 illustrates a schematic circuit implementation of a superconducting parametric gyrator device 1100 which is based, at least in part, on the 6-pole parametric bandpass filter network configuration of FIG. 5, but which implements parametric coupling circuits using single Josephson junctions. More specifically, the superconducting parametric gyrator device 1100 comprises a parametric multipole bandpass filter 1110, which is operated under the control of a control system 1120 which comprises a first control signal generator 1120-1 that generates a first control signal Pump_1, and a second control signal generator 1120-2 that generates a second control signal Pump_2.

The parametric multipole bandpass filter 1110 comprises a first I/O port P1, a second I/O port P2, and a multipole bandpass filter network comprising six (6) resonator circuits and seven (7) coupling circuits. In particular, the parametric multipole bandpass filter 1110 comprises a first resonator circuit 1112-1, a second resonator circuit 1112-2, a third resonator circuit 1112-3, a fourth resonator circuit 1112-4, a fifth resonator circuit 1112-5, and a sixth resonator circuit 1112-6 (collectively, resonator circuits 1112). The coupling circuits comprise five (5) linear couplers implemented by coupling capacitors including a first coupling capacitor C₁, a second coupling capacitor C₂, a third coupling capacitor C₃, a fourth coupling capacitor C₄, and a fifth coupling capacitor C₅. In addition, the coupling circuits comprise two parametric couplers including a first parametric coupler 1114-1 and a second parametric coupler 1114-2. The first parametric coupler 1114-1 is coupled to a first node n1 of the parametric multipole bandpass filter 1110, and the second parametric coupler 1114-2 is coupled to a second node n2 of the parametric multipole bandpass filter 1110.

FIG. 11 illustrates an exemplary embodiment in which the first and second parametric couplers 1114-1 and 114-2 are implemented using single Josephson junctions, which are current pumped to perform 3-wave or 4-wave parametric frequency mixing operations of the superconducting parametric gyrator device 1100. In particular, the first parametric coupler 1114-1 comprises a first Josephson junction J₁ which is coupled to and between the first node n1 and ground GND, and the second parametric coupler 1114-2 comprises a second Josephson junction J₂ which is coupled to and between the second node n2 and ground GND. In some embodiments, the first and second Josephson junctions J₁ and J₂ are nomically identical devices which have the same critical current.

The parametric multipole bandpass filter 1110 comprises a first filter section 1110-1, a second filter section 1110-2, and a third filter section 1110-3, providing a multiband bandpass filter network which comprises an idler band B_{Idler} and signal bands B_{Signal}, wherein the first, second, and third filter sections 1110-1, 1110-2, and 1110-2 each comprise two resonator circuits (2 poles). In some embodiments, such as shown in FIG. 11, the parametric multipole bandpass filter 1110 comprises an immittance inverting bandpass filter circuit architecture and layout which is the same or similar to that of the parametric multipole bandpass filter 510 discussed in detail above in conjunction with FIG. 5, the details of which will not be repeated. It is to be understood, however, that the parametric multipole bandpass filter 1110 can be implemented using any suitable parametric multipole bandpass filter architecture, with any number of poles, as desired for a given application.

In the exemplary configuration of FIG. 11, the first and second pump signals Pump_1 and Pump_2 are AC current signals which have the same frequency fₚ, but the first control signal Pump_1 has a first phase φ₁ and the second control signal Pump_2 has a second phase φ₂, which differs from the first phase φ₁. The first control signal Pump_1 is applied to the first parametric coupler circuit 1114-1 to drive the first Josephson junction J₁, and the second control signal Pump_2 is applied to the second parametric coupler circuit 1114-2 to drive the second Josephson junction J₂, to thereby perform three-wave or 4-wave parametric frequency mixing operations, as discussed above, to achieve non-reciprocal gyration, depending on the direction of RF signal flow between the first and second ports P1 and P2 of the superconducting parametric gyrator device 1100. In some embodiments, the first and second control signals Pump_1 and Pump_2 have current magnitudes that do not exceed, e.g., 0.8*I_{C}, where I_{C} denotes the critical current of the first and second Josephson junctions J₁ and J₂, to ensure that the first and second Josephson junctions J₁ and J₂ do not switch to resistive regimes during operation of the superconducting parametric gyrator device 1100.

The superconducting parametric gyrator device 1100 can operate in a three-wave parametric frequency mixing mode when the first and second control signals Pump_1 and Pump_2 have DC offsets, or a four-wave parametric frequency mixing mode when the first and second control signals Pump_1 and Pump_2 have no DC offsets. As with the exemplary embodiments discussed above, the superconducting parametric gyrator device 1100 will convert an input RF signal having a frequency fₛ and phase θ into an output RF signal having the same frequency fₛ, but with a different phase of 0 ±Δ_{φ}, depending on the direction of RF power flow through the superconducting parametric gyrator device 1100, where Δ_{φ}=φ₁−φ₂ for a three-wave parametric frequency mixing mode of operation or where Δ_{φ}=2(φ₁−φ₂) for a four-wave parametric frequency mixing mode of operation. In some embodiments, a microwave bias T can be utilized in conjunction with the first and second control signal generators 1120-1 and 1120-2 to combine DC and AC control signals to generate the first and second control signals Pump_1 and Pump_2. In other embodiments, the first and second control signal generators 1120-1 and 1120-2 can be implemented using arbitrary wave generators (AWGs) that are configured to generate the first and second AC control signals Pump_1 and Pump_2 either with or without DC offsets, as desired, for a given mode of operation.

In the exemplary configuration of the superconducting parametric gyrator device 1100 shown in FIG. 11, a first filter 1125-1 is coupled between an output of the first control signal generator 1120-1 and the first node n1 of the parametric multipole bandpass filter 1110, and a second filter 1125-2 is coupled between an output of the second control signal generator 1120-2 and the second node n2 of the parametric multipole bandpass filter 1110. The first and second filters 1125-1 and 1125-2 are utilized to ensure that the parametric multipole bandpass filter 1110 sees the first and second control signal generators 1120-1 and 1120-2 as an infinite impedance (e.g., open circuit) at the nodes n1 and n2 and thereby avoid loading the first and second Josephson junctions J₁ and J₂ of the first and second parametric couplers 1114-1 and 1114-2. In some embodiments, the first and second filters 1125-1 and 1125-2 are implemented using single-ended low pass filters that are configured to pass RF signals at the pump signal frequency fₚ (e.g., fₚ=3.0 GHz), while blocking RF signals in the signal band B_{Signal} and the idler band B_{Idler}.

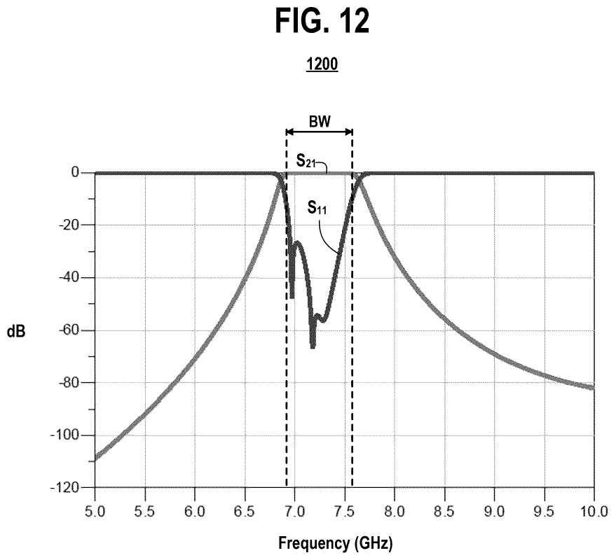

Next, FIG. 12 graphically illustrates simulated scattering parameters of a superconducting parametric gyrator device, according to another exemplary embodiment. In particular, FIG. 12 graphically illustrates simulated scattering parameters of a superconducting parametric gyrator device having a simulated circuit model based on the superconducting parametric gyrator device 1100 of FIG. 11. FIG. 12 illustrates a graph 1200 which shows simulated scattering parameters of the simulated superconducting parametric gyrator device in terms of dB (y-axis) as a function of frequency in GHz (x-axis) over a range of 5.0 GHz to 10.0 GHz, wherein the parametric multipole bandpass filter 1110 of FIG. 11 (6-pole bandpass filter) is modeled to have a signal band B_{Signal} with a center signal frequency of fₛ=7.25 GHz. In particular, FIG. 12 illustrates (i) a simulated transmission parameter S₂₁ which represents RF power transmission from the first I/O port P1 to the second I/O port, and (ii) a simulated reflection parameter S₁₁ which represent RF power reflection at the first I/O port P1. FIG. 12 illustrates that the transmission parameter S₂₁ is near unity in the signal passband B_{Signal} over a bandwidth BW of ~700 MHz from ~6.9 GHz to ~7.6 GHz. In addition, FIG. 12 illustrates an in-band rejection Si of greater than −20 dB over the bandwidth BW of the signal passband B_{Signal}, and greater than −60 dB near the center frequency fₛ.

It is to be noted that advantageously, exemplary embodiments of the disclosure provide superconducting parametric gyrator circuits which are configured to provide non-reciprocal phase shifting (gyration) using parametric frequency mixing, as opposed to conventional ferrite-based microwave gyrator designs that utilize, e.g., ferrite elements such as circular ferrite rods, to achieve non-reciprocal gyration through Faraday rotations. In addition, the exemplary superconducting parametric gyrator circuits as disclosed herein can be utilized to construct various superconducting microwave circuits such as superconducting isolators and superconducting, which can be used in place of current state of the art bulky, magnetic (ferrite-based) isolator devices and circulator devices in a quantum computing system. The exemplary superconducting isolator circuits and superconducting circulator circuits as discussed herein have much smaller footprints and sizes (e.g., 200 square microns) as compared to ferrite-based isolator devices and circulator devices, which allows, e.g., qubit readout signal chains to have decreasingly smaller physical footprints, which allows for increasing density of readout wiring and higher circuit integration density, while eliminating the presence of large stray magnetic fields in a dilution refrigerator (or cryostat) which would otherwise be generated by implementing ferrite-based, magnetic isolator and circulator devices. In addition, the exemplary superconducting isolator and circular devices as described herein are low power elements that would not unduly increase the thermal loading in a dilution refrigerator (or cryostat).

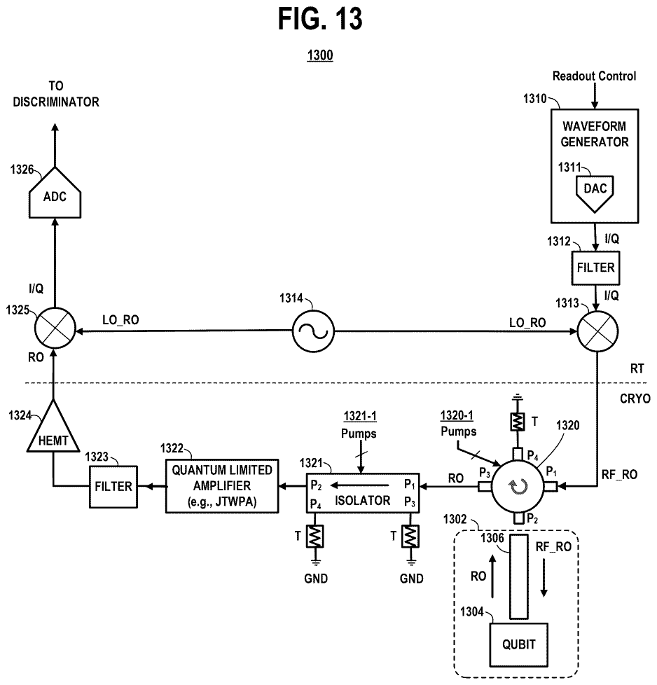

FIG. 13 schematically illustrates readout circuitry of a quantum processing system, which comprises superconducting isolator and circulator devices that are implemented using superconducting parametric gyrator circuits, according to an exemplary embodiment of the disclosure. More specifically, FIG. 13 schematically illustrates qubit readout circuitry 1300 of a quantum computing system which is configured to readout a quantum state of at least one superconducting qubit. For example, the qubit readout circuitry 1300 comprises a qubit-resonator circuit 1302 comprising a superconducting qubit 1304 and a readout resonator 1306. The readout resonator 1306 is capacitively coupled to the superconducting qubit 1304, thereby providing a qubit/resonator system which is configured to enable a dispersive qubit readout operation.

FIG. 13 illustrates an exemplary embodiment in which the qubit readout circuitry 1300 comprises control circuitry which implements a heterodyne I/Q modulation and mixing system for qubit readout. For example, the qubit readout circuitry 1300 comprises a control signal chain which comprises a waveform generator 1310 (or pulse envelope generator) which comprises digital-to-analog (DAC) circuitry 1311, low-pass filter circuitry 1312, a first I/Q mixer 1313 (upconverter or downconverter mixer), and a local oscillator (LO) signal generator 1314, which are configured to generate an RF readout control signal (RF_RO) to readout the state of the superconducting qubit 1304 using a dispersive readout scheme. In addition, the qubit readout circuitry 1300 comprises a readout signal chain which comprises a superconducting circulator 1320, a superconducting isolator 1321, a quantum-limited amplifier (QLA) 1322 (e.g., a Josephson traveling wave amplifier (JTWPA)), a filter 1323, a high-electron-mobility-transistor (HEMT) amplifier 1324, a second I/Q mixer 1325, and analog-to-digital converter (ADC) circuitry 1326, which outputs digital readout signals to a hardware or software-based discriminator to determine a readout state of the superconducting qubit 1304.

The superconducting circulator 1320 is controlled by pump signals 1320-1, and the superconducting isolator 1321 is controlled by pump signals 1321-1. In some embodiments, the superconducting circulator 1320 and the superconducting isolator 1321 are nominally identical circuits, except that certain ports are terminated with matched termination T for the given use of operation. For example, in some embodiments, the superconducting circulator 1320 and the superconducting isolator 1321 can be implemented using any one of the exemplary circuit architectures as shown in FIGS. 7A and 9 which implement the superconducting parametric gyrator circuit of FIG. 5, or alternatively, the exemplary superconducting parametric gyrator circuit of FIG. 11, etc. As schematically illustrated in FIG. 13, the superconducting circulator 1320 comprises a first port P₁, a second port P₂, a third port P₃, and a fourth port P₄, wherein the first port P₁ is coupled to an output of the first I/Q mixer 1313, the second port P₂ is coupled to the readout resonator 1306, the third port P₃ is coupled to an input port (first port P1) of the superconducting isolator 1321, and the fourth port P₄ is terminated by a matched Z₀ termination T₁. In addition, the superconducting isolator 1321 comprises a first port P₁, a second port P₂, a third port P₃, and a fourth port P₄, wherein the first port P₁ is coupled to the third port P₃ of the superconducting circulator 1320, the second port P₂ is coupled to an input of the QLA 1322, and wherein the third and fourth ports P₃ and P₄ are terminated by matched Z₀ terminations T.

The waveform generator 1310 is configured to generate and output analog I and Q control signals with a given type of pulse envelope (e.g., Gaussian square pulse envelope) for qubit state readout, in response to a readout control signal. The analog I and Q control pulses are filtered by the low-pass filter circuitry 1312. The filtered analog control I and Q control pulses are applied to the first I/Q mixer 1313, along with an LO signal (LO_RO) that is generated by the LO signal generator 1314, to generate the RF readout control signal RF_RO. In particular, the first I/Q mixer 1313 is configured mix the analog I and Q control pulses with the LO_RO signal of a given LO frequency (e.g., 7 GHz) to perform I/Q modulation and up-conversion and/or down-conversion using known techniques (e.g., single sideband modulation) to generate the RF readout control signal RF_RO.

In the dispersive regime of qubit-resonator coupling, the RF readout control signal RF_RO (with the requisite frequency tone, pulse envelope shape, and pulse duration) interacts with the given qubit-resonator circuit 1302 in a manner which results in the generation of readout signal RO that is reflected out from the readout resonator 1306. The readout signal RO comprises information (e.g., phase and/or amplitude) that is qubit-state dependent. In other words, the dispersive readout process yields an RF readout signal RO having a state-dependent phasor response, which is analyzed to discriminate the quantum state of the superconducting qubit 1304.

As schematically illustrated in FIG. 13, the RF readout control signal RF_RO is applied to the first port P₁ of the superconducting circulator 1320, and routed to the second port P2 of the superconducting circulator 1320, where the RF readout control signal RF_RO is coupled to the readout resonator 1306. The resulting readout signal RO is applied to the second port P₂ of the superconducting circulator 1320, and routed to the third port P₃ of the superconducting circulator 1320, wherein the readout signal RO is output from the third port P₃ of the superconducting circulator 1320 and applied to the readout signal chain. In the readout signal chain, the readout signal RO is applied to the first port P₁ of the superconducting isolator 1321 and routed to the second port P₂ thereof, where the readout signal RO is applied to an input port of the QLA 1322 which amplifies the readout signal RO. The amplified readout signal RO, which is output from the QLA 1322, is filtered by the filter 1323, flows through another optional isolator, is amplified by the HEMT amplifier 1324, and then applied to an input of the second I/Q mixer 1325. The second I/Q mixer 1325 mixes the amplified and filtered RF readout signal RO with the LO_RO signal to perform a down conversion operation where the RF readout signal RO is down converted and split into analog I and Q signals. The analog I and Q signals are input to the ADC circuitry 1326 and sampled by the ADC circuitry 1326 to generate respective digital I and Q signals that are indicative of the amplitude and phase of the readout signal RO. A discriminator (e.g., hardware and/or software-based discriminator) analyzes the digital I and Q signals to discriminate the measured quantum state of the superconducting qubit 1304 based on the amplitude and phase components of the RF readout signal RO.

In some embodiments, the pump signals 1320-1 applied to the superconducting circulator 1320 are configured to implement parametric frequency mixing to enable signal routing of the four-port circulator as discussed above. Moreover, with the exemplary configuration of the superconducting circulator 1320 as shown in FIG. 13, the RF_RO signal entering port P₁ is routed to port P₂ (P₁→P₂) and the RO signal entering port P₂ is routed to port P₃ (P₂→P₃). Moreover, back propagating RF signals from the downstream components of the readout signal chain which enter port P₃ are routed to port P₄ (P₃→P₄) which is terminated with the matched load T to ground GND. In this regard, with the exemplary configuration of the superconducting circulator 1320 shown in FIG. 13, since the fourth port P₄ is terminated, the superconducting circulator 1320 provides isolation to protect the state of the superconducting qubit 1304 from being perturbed by RF signals that may backpropagate from the readout signal chain and enter the third port P3 since such backpropagating RF signals would be routed to the fourth port P4 and terminated to ground GND.

Moreover, in the exemplary embodiment of FIG. 13, the superconducting isolator 1321 would provide further isolation of the qubit-resonator circuit 1302 from back propagating RF signals from the downstream components (e.g., amplifiers 1322 and 1324 and electronics), which can adversely impact the qubit-resonator circuit 1302 and other qubits and readout resonators of a quantum processor unit (QPU).

It is to be understood that FIG. 13 is an exemplary non-limiting embodiment which schematically illustrates a high-level schematic illustration of readout control circuitry. The qubit readout circuitry 1300 and readout signal chain can be implemented using other components and configurations. For example, the qubit-resonator circuit 1302 can implement a Purcell filter that is designed, for example, to pass at the frequency of the readout signal RO while blocking the transmission of energy at the qubit frequency, to enhance the qubit lifetime, and perform other functions as understood by those of ordinary skill in the art. The Purcell filter allows the readout resonator 1306 to have relatively large bandwidth to increase the coupling between the readout resonator 1306 and a readout line coupled to the second port P2 of the superconducting circulator 1320 and thereby increase readout speed, while suppressing the Purcell effect (energy decay). In this regard, the Purcell filter enhances the coherence time (T₁) of the superconducting qubit 1304, which could otherwise be limited by a large readout resonator bandwidth in the absence of the Purcell filter.

Further, a frequency-multiplexed readout system (which implements frequency domain multiplexing) can be utilized to scale-up a readout chain in a quantum computing system for reading the quantum states of superconducting qubits in relatively large superconducting quantum computers. In a frequency-multiplexed readout system, multiple readout resonators (with different resonance frequencies) are coupled to separate qubits and commonly coupled to a shared readout bus. For example, in the exemplary embodiment of FIG. 13, the superconducting circulator 1320 can be replaced by a shared readout bus that is coupled to a plurality of readout resonators of a plurality of corresponding qubit, wherein the shared readout bus is configured to allow the transmission of multiple readout signals with readout frequencies which match the resonance frequencies of the readout resonators, and, thus simultaneously read out the quantum states of multiple qubits using one input and one output line.

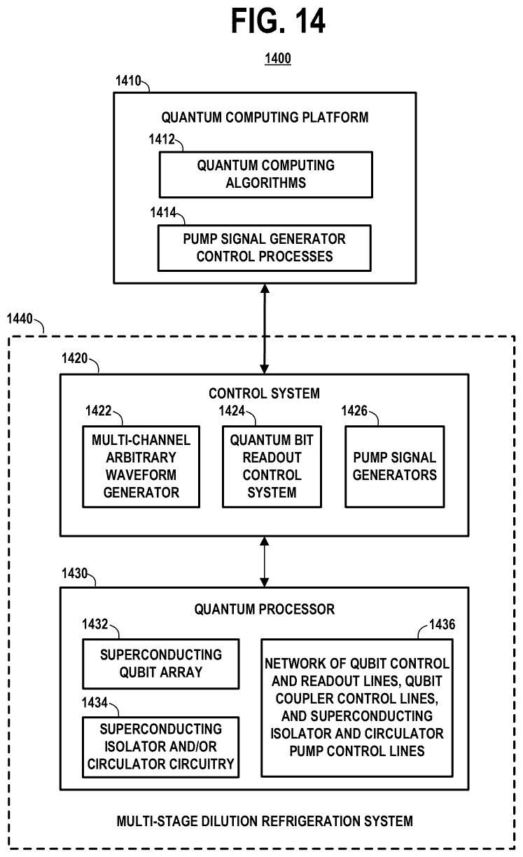

FIG. 14 schematically illustrates a quantum computing system which comprises superconducting isolator and circulator devices, according to an exemplary embodiment of the disclosure. In particular, FIG. 14 schematically illustrates a quantum computing system 1400 which comprises a quantum computing platform 1410, a control system 1420, and a quantum processor 1430 (or quantum processing unit (QPU)). The quantum processor 1430 comprises one or more solid-state quantum chips which comprise, e.g., a superconducting qubit array 1432 (which comprises, e.g., an array of superconducting qubits and qubit couplers to mediate interactions between qubits, superconducting isolator and/or circulator circuitry 1434, and a network of control and readout lines 1436 (including, for example, qubit control and readout lines, qubit coupler control lines, and pump control lines for controlling the superconducting isolator and circulator circuitry, etc.), and other circuit QED components that may be needed for a given application or quantum system configuration. The superconducting isolator and circulator circuitry 1434 is implemented using any of the exemplary embodiments as discussed above.

In some embodiments, the quantum computing platform 1410 implements a software platform that is configured to program a quantum computer to execute quantum computing algorithms 1412 which are implemented using, e.g., quantum circuits which define computational routings consisting of coherent quantum operations on quantum data, such as qubits. In addition, in some embodiments, the quantum computing platform 1410 implements software control processes 1414 to control and synchronize the generation of pump control signals to control parametric frequency mixing operations performed by superconducting circulator and/or isolator circuits which implement superconducting parametric gyrator circuits, as discussed herein.

In addition, in some embodiments, the control system 1420 comprises a multi-channel arbitrary waveform generator 1422, a quantum bit readout control system 1424, and pump signal generators 1426. In some embodiments, the control system 1420 and the quantum processor 1430 are disposed in a dilution refrigeration system 1440 which can generate cryogenic temperatures that are sufficient to operate components of the control system 1420 for quantum computing applications. For example, the quantum processor 1430 may need to be cooled down to near-absolute zero, e.g., 10-15 millikelvin (mK), to allow the superconducting qubits to exhibit quantum behaviors. In some embodiments, the dilution refrigeration system 1440 comprises a multi-stage dilution refrigerator where the components of the control system 1420 can be maintained at different cryogenic temperatures, as needed. For example, while the quantum processor 1430 may need to be cooled down to, e.g., 10-15 mK, the circuit components of the control system 1420 may be operated at cryogenic temperatures greater than 10-15 mK (e.g., cryogenic temperatures in a range of 3K-4K), depending on the configuration of the quantum computing system. In some embodiments, the entirety of the control system 1420, or some components thereof, are disposed in a room temperature environment.

In some embodiments, as noted above, the superconducting qubit array 1432 comprises an array of superconducting qubits, superconducting qubit couplers, and other components commonly utilized to support quantum processing using qubits. The number of superconducting qubits of the superconducting qubit array 1432 can be on the order of tens, hundreds, thousands, or more, etc. The network of control and readout line 1436 is configured to apply control signals to superconducting qubits and coupler circuitry in the superconducting qubit array 1432 to perform various types of gate operations, e.g., single-gate operations, entanglement gate operations, perform error correction operations, etc., as well as read the quantum states of the superconducting qubits. For example, microwave control pulses are applied to the qubit control lines of respective superconducting qubits to change the quantum state of the superconducting qubits (e.g., change the quantum state of a given qubit between the ground state and excited state, or to a superposition state) when executing quantum information processing algorithms.

Furthermore, as noted above, the qubit readout lines include qubit readout resonators that are coupled to respective superconducting qubits. The state of a given superconducting qubit can be determined through microwave transmission or reflection measurements using the readout ports of the readout resonator. The states of the superconducting qubits are read out after executing a quantum algorithm. In some embodiments, as noted above, a dispersive readout operation is performed in which a change in the resonant frequency of a given readout resonator, which is coupled to a given superconducting qubit, is utilized to readout the state (e.g., ground or excited state) of the given superconducting qubit.

The network of control and readout lines 1436 is coupled to the control system 1420 through a suitable hardware input/output (I/O) interface, which couples I/O signals between the control system 1420 and the quantum processor 1430. For example, the hardware I/O interface may comprise various types of hardware and components, such as RF cables, wiring, RF elements, optical fibers, heat exchanges, filters, amplifiers, isolators, etc.

In some embodiments, the multi-channel AWG 1422 and other suitable microwave pulse signal generators are configured to generate the microwave control pulses that are applied to the qubit drive lines, and the coupler drive lines to control the operation of the superconducting qubits and associated qubit coupler circuitry, when performing various gate operations to execute a given certain quantum information processing algorithm. In some embodiments, the multi-channel AWG 1422 comprises a plurality of AWG channels, which control respective superconducting qubits within the superconducting qubit array 1432 of the quantum processor 1430. In some embodiments, each AWG channel comprises a baseband signal generator, a digital-to-analog converter (DAC) stage, a filter stage, a modulation stage, an impedance matching network, and a phase-locked loop system to generate local oscillator (LO) signals (e.g., quadrature LO signals LO_I and LO_Q) for the respective modulation stages of the respective AWG channels.

In some embodiments, the multi-channel AWG 1422 comprises a quadrature AWG system which is configured to process quadrature signals, wherein a quadrature signal comprises an in-phase (I) signal component, and a quadrature-phase (Q) signal component. In each AWG channel the baseband signal generator is configured to receive baseband data as input (e.g., from the quantum computing platform), and generate digital quadrature signals I and Q which represent the input baseband data. In this process, the baseband data that is input to the baseband signal generator for a given AWG channel is separated into two orthogonal digital components including an in-phase (I) baseband component and a quadrature-phase (Q) baseband component. The baseband signal generator for the given AWG channel will generate the requisite digital quadrature baseband IQ signals which are needed to generate an analog waveform (e.g., sinusoidal voltage waveform) with a target center frequency that is configured to operate or otherwise control a given quantum bit that is coupled to the output of the given AWG channel.

The DAC stage for the given AWG channel is configured to convert a digital baseband signal (e.g., a digital IQ signal output from the baseband signal generator) to an analog baseband signal (e.g., analog baseband signals I(t) and Q(t)) having a baseband frequency. The filter stage for the given AWG channel is configured to filter the IQ analog signal components output from the DAC stage to thereby generate filtered analog IQ signals. The modulation stage for the given AWG channel is configured to perform analog IQ signal modulation (e.g., single-sideband (SSB) modulation) by mixing the filtered analog signals I(t) and Q(t), which are output from the filter stage, with quadrature LO signals (e.g., an in-phase LO signal (LO_I) and a quadrature-phase LO signal (LO_Q)) to generate and output an analog RF signal (e.g., a single-sideband modulated RF output signal).

In some embodiments, the quantum bit readout control system 1424 comprises a microwave pulse signal generator that is configured to apply a microwave tone to a given readout resonator line of a given superconducting qubit to perform a readout operation to readout the state of the given superconducting qubit, as well as circuitry that is configured to process the readout signal generated by the readout resonator line to determine the state of the given superconducting qubit, using techniques known to those of ordinary skill in the art. In some embodiments, the quantum bit readout control system 1424 is implemented based on the readout circuitry of FIG. 13.

The quantum computing platform 1410 comprises a software and hardware platform which comprises various software layers that are configured to perform various functions, including, but not limited to, generating and implementing various quantum applications using suitable quantum programming languages, configuring and implementing various quantum gate operations, compiling quantum programs into a quantum assembly language, implementing and utilizing a suitable quantum instruction set architecture (ISA), performing calibration operations to calibrate the quantum circuit elements and gate operations, etc. In addition, the quantum computing platform 1410 comprises a hardware architecture of processors, memory, etc., which is configured to control the execution of quantum applications, and interface with the control system 1420 to (i) generate digital control signals that are converted to analog microwave control signals by the control system 1420, to control operations of the quantum processor 1430 when executing a given quantum application, and (ii) to obtain and process digital signals received from the control system 1420, which represent the processing results generated by the quantum processor 1430 when executing various gate operations for a given quantum application.

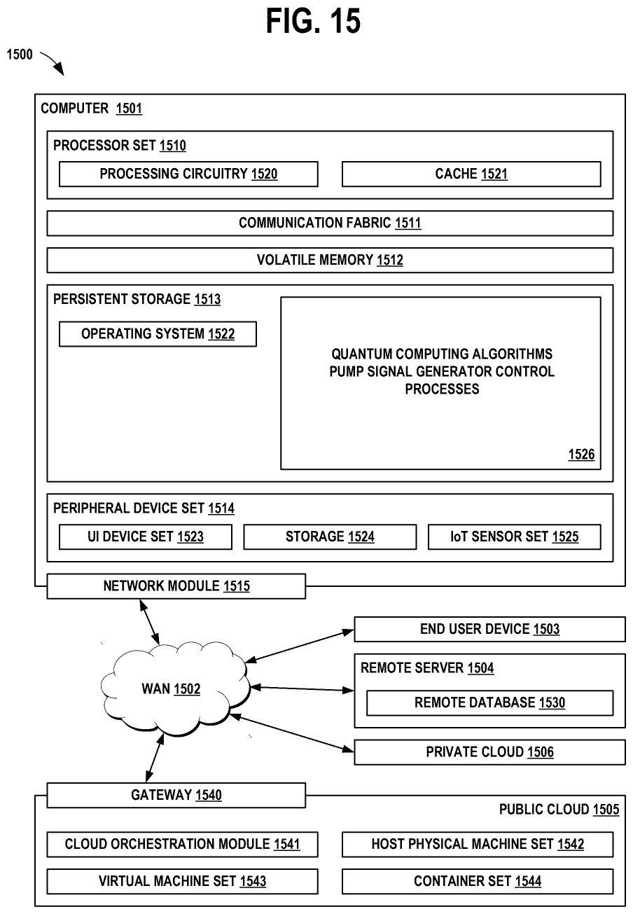

In some embodiments, the quantum computing platform 1410 of the quantum computing system 1400 may be implemented using any suitable computing system architecture (e.g., as shown in FIG. 15) which is configured to implement methods to support quantum computing operations by executing computer readable program instructions that are embodied on a computer program product which includes a computer readable storage medium (or media) having such computer readable program instructions thereon for causing a processor to perform control methods as discussed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

For example, FIG. 15 schematically illustrates an exemplary architecture of a computing node which can host a quantum computing platform of the quantum computing system of FIG. 14, according to an exemplary embodiment of the disclosure. In particular, FIG. 15 schematically illustrates a computing environment 1500 which contains an example of an environment for the execution of at least some of the computer code (block 1526) involved in executing quantum computing algorithms (e.g., quantum computing algorithms 912, FIG. 9). In addition to block 1526, computing environment 1500 includes, for example, computer 1501, wide area network (WAN) 1502, end user device (EUD) 1503, remote server 1504, public cloud 1505, and private cloud 1506. In this embodiment, computer 1501 includes processor set 1510 (including processing circuitry 1520 and cache 1521), communication fabric 1511, volatile memory 1512, persistent storage 1513 (including operating system 1522 and block 1526, as identified above), peripheral device set 1514 (including user interface (UI), device set 1523, storage 1524, and Internet of Things (IoT) sensor set 1525), and network module 1515. Remote server 1504 includes remote database 1530. Public cloud 1505 includes gateway 1540, cloud orchestration module 1541, host physical machine set 1542, virtual machine set 1543, and container set 1544.

Computer 1501 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1530. As is well understood in the art of computer technology, and depending upon the technology, performance of a computer-implemented method may be distributed among multiple computers and/or between multiple locations. On the other hand, in this presentation of computing environment 1500, detailed discussion is focused on a single computer, specifically computer 1501, to keep the presentation as simple as possible. Computer 1501 may be located in a cloud, even though it is not shown in a cloud in FIG. 15. On the other hand, computer 1501 is not required to be in a cloud except to any extent as may be affirmatively indicated.

Processor set 1510 includes one, or more, computer processors of any type now known or to be developed in the future. Processing circuitry 1520 may be distributed over multiple packages, for example, multiple, coordinated integrated circuit chips. Processing circuitry 1520 may implement multiple processor threads and/or multiple processor cores. Cache 1521 is memory that is located in the processor chip package(s) and is typically used for data or code that should be available for rapid access by the threads or cores running on processor set 1510. Cache memories are typically organized into multiple levels depending upon relative proximity to the processing circuitry. Alternatively, some, or all, of the cache for the processor set may be located “off chip.” In some computing environments, processor set 1510 may be designed for working with qubits and performing quantum computing.

Computer readable program instructions are typically loaded onto computer 1501 to cause a series of operational steps to be performed by processor set 1510 of computer 1501 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1521 and the other storage media discussed below. The program instructions, and associated data, are accessed by processor set 1510 to control and direct performance of the inventive methods. In computing environment 1500, at least some of the instructions for performing the inventive methods may be stored in block 1526 in persistent storage 1513.

Communication fabric 1511 is the signal conduction paths that allow the various components of computer 1501 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 1512 is any type of volatile memory now known or to be developed in the future. Examples include dynamic type random access memory (RAM) or static type RAM. Typically, the volatile memory is characterized by random access, but this is not required unless affirmatively indicated. In computer 1501, the volatile memory 1512 is located in a single package and is internal to computer 1501, but, alternatively or additionally, the volatile memory may be distributed over multiple packages and/or located externally with respect to computer 1501.

Persistent storage 1513 is any form of non-volatile storage for computers that is now known or to be developed in the future. The non-volatility of this storage means that the stored data is maintained regardless of whether power is being supplied to computer 1501 and/or directly to persistent storage 1513. Persistent storage 1513 may be a read only memory (ROM), but typically at least a portion of the persistent storage allows writing of data, deletion of data and re-writing of data. Some familiar forms of persistent storage include magnetic disks and solid-state storage devices. Operating system 1522 may take several forms, such as various known proprietary operating systems or open-source Portable Operating System Interface type operating systems that employ a kernel. The code included in block 1526 typically includes at least some of the computer code involved in performing the inventive methods.

Peripheral device set 1514 includes the set of peripheral devices of computer 1501. Data communication connections between the peripheral devices and the other components of computer 1501 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1523 may include components such as a display screen, speaker, microphone, wearable devices (such as goggles and smart watches), keyboard, mouse, printer, touchpad, game controllers, and haptic devices. Storage 1524 is external storage, such as an external hard drive, or insertable storage, such as an SD card. Storage 1524 may be persistent and/or volatile. In some embodiments, storage 1524 may take the form of a quantum computing storage device for storing data in the form of qubits. In embodiments where computer 1501 is required to have a large amount of storage (for example, where computer 1501 locally stores and manages a large database) then this storage may be provided by peripheral storage devices designed for storing very large amounts of data, such as a storage area network (SAN) that is shared by multiple, geographically distributed computers. IoT sensor set 1525 is made up of sensors that can be used in Internet of Things applications. For example, one sensor may be a thermometer and another sensor may be a motion detector.

Network module 1515 is the collection of computer software, hardware, and firmware that allows computer 1501 to communicate with other computers through WAN 1502. Network module 1515 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1515 are performed on the same physical hardware device. In other embodiments (for example, embodiments that utilize software-defined networking (SDN)), the control functions and the forwarding functions of network module 1515 are performed on physically separate devices, such that the control functions manage several different network hardware devices. Computer readable program instructions for performing the inventive methods can typically be downloaded to computer 1501 from an external computer or external storage device through a network adapter card or network interface included in network module 1515.

WAN 1502 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 1503 is any computer system that is used and controlled by an end user (for example, a customer of an enterprise that operates computer 1501), and may take any of the forms discussed above in connection with computer 1501. EUD 1503 typically receives helpful and useful data from the operations of computer 1501. For example, in a hypothetical case where computer 1501 is designed to provide a recommendation to an end user, this recommendation would typically be communicated from network module 1515 of computer 1501 through WAN 1502 to EUD 1503. In this way, EUD 1503 can display, or otherwise present, the recommendation to an end user. In some embodiments, EUD 1503 may be a client device, such as thin client, heavy client, mainframe computer, desktop computer and so on.

Remote server 1504 is any computer system that serves at least some data and/or functionality to computer 1501. Remote server 1504 may be controlled and used by the same entity that operates computer 1501. Remote server 1504 represents the machine(s) that collect and store helpful and useful data for use by other computers, such as computer 1501. For example, in a hypothetical case where computer 1501 is designed and programmed to provide a recommendation based on historical data, then this historical data may be provided to computer 1501 from remote database 1530 of remote server 1504.

Public cloud 1505 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1505 is performed by the computer hardware and/or software of cloud orchestration module 1541. The computing resources provided by public cloud 1505 are typically implemented by virtual computing environments that run on various computers making up the computers of host physical machine set 1542, which is the universe of physical computers in and/or available to public cloud 1505. The virtual computing environments (VCEs) typically take the form of virtual machines from virtual machine set 1543 and/or containers from container set 1544. It is understood that these VCEs may be stored as images and may be transferred among and between the various physical machine hosts, either as images or after instantiation of the VCE. Cloud orchestration module 1541 manages the transfer and storage of images, deploys new instantiations of VCEs and manages active instantiations of VCE deployments. Gateway 1540 is the collection of computer software, hardware, and firmware that allows public cloud 1505 to communicate through WAN 1502.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 1506 is similar to public cloud 1505, except that the computing resources are only available for use by a single enterprise. While private cloud 1506 is depicted as being in communication with WAN 1502, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1505 and private cloud 1506 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
a superconducting parametric gyrator circuit comprising:
a first input/output (I/O) port and a second I/O port; and
a parametric multipole bandpass filter circuit coupled between the first I/O port and the second I/O port;
wherein the parametric multipole bandpass filter circuit is responsive to a first control signal and a second control signal, which have a same frequency but different phases, to perform parametric frequency mixing of the first and second control signals with an input signal applied to the first I/O port or the second I/O port, to generate an output signal which has a same frequency as the input signal and a non-reciprocal phase shift based on a phase difference between the first control signal and the second control signal, and based on a direction of propagation of the input signal between the first I/O port and the second I/O port.

2. The device of claim 1, wherein the parametric multipole bandpass filter circuit comprises:
a first linear filter section, a second linear filter section, and a third linear filter section;
a first parametric coupling circuit configured to parametrically couple the first linear filter section and the second linear filter section; and
a second parametric coupling circuit configured to parametrically couple the second linear filter section and the third linear filter section.

3. The device of claim 2, wherein:
the first parametric coupling circuit comprises a first non-linear inductance circuit which is responsive to the first control signal to cause a first parametric frequency conversion of a signal propagating between the first linear filter section and the second linear filter section; and
the second parametric coupling circuit comprises a second non-linear inductance circuit which is responsive to the second control signal to cause a second parametric frequency conversion of a signal propagating between the second linear filter section and the third linear filter section.

4. The device of claim 3, wherein the first non-linear inductance circuit and the second non-linear inductance circuit each comprise a direct current superconducting quantum interference device.

5. The device of claim 3, wherein the first non-linear inductance circuit and the second non-linear inductance circuit each comprise a single Josephson junction.

6. The device of claim 2, wherein:
the first linear filter section and the third linear filter section each comprise an immittance inverting bandpass filter having a first passband with a first center frequency; and
the second linear filter section comprises an immittance inverting bandpass filter having a second passband with a second center frequency, different from the first center frequency.

7. The device of claim 6, wherein:
the first parametric coupling circuit is responsive to the first control signal to perform a first parametric frequency conversion to convert a signal frequency between a first frequency in the first passband and a second frequency in the second passband, and apply a first phase shift based on a phase of the first control signal;
the second parametric coupling circuit is responsive to the second control signal to perform a second parametric frequency conversion to convert a signal frequency between a first frequency in the first passband and a second frequency in the second passband, and apply a second phase shift based on a phase of the second control signal.

8. The device of claim 1, wherein one of the first control signal or the second control signal is an amplitude modulated control signal.

9. The device of claim 1, wherein the superconducting parametric gyrator circuit is a component of a superconducting isolator circuit.

10. The device of claim 1, wherein the superconducting parametric gyrator circuit is a component of a superconducting circulator circuit.

11. A device, comprising:
a parametric multipole bandpass filter circuit comprising:
a first linear filter section coupled to a first input/output I/O port, a second linear filter section, and a third linear filter section coupled to a second I/O port;
a first parametric coupling circuit which parametrically couples the first linear filter section and the second linear filter section; and
a second parametric coupling circuit which parametrically couples the second linear filter section and the third linear filter section.

12. The device of claim 11, wherein the parametric multipole bandpass filter circuit is responsive to a first control signal applied to the first parametric coupling circuit and a second control signal applied to the second parametric coupling circuit, the first and second control signals having a same frequency and different phases, to perform parametric frequency mixing of the first and second control signals with an input signal applied to one of the first I/O port and the second I/O port, to generate an output signal which has a same frequency as the input signal and which has a phase shift which is based on (i) a phase difference between the first control signal and the second control signal, and (ii) a direction of propagation of the input signal between the first I/O port and the second I/O port.

13. The device of claim 12, wherein:
the first parametric coupling circuit comprises a first non-linear inductance circuit which is responsive to the first control signal to cause a first parametric frequency conversion of a signal propagating between the first linear filter section and the second linear filter section; and
the second parametric coupling circuit comprises a second non-linear inductance circuit which is responsive to the second control signal control signal to cause a second parametric frequency conversion of a signal propagating between the second linear filter section and the third linear filter section.

14. The device of claim 13, wherein the first non-linear inductance circuit and the second non-linear inductance circuit each comprise a direct current superconducting quantum interference device.

15. The device of claim 13, wherein the first non-linear inductance circuit and the second non-linear inductance circuit each comprise a single Josephson junction.

16. The device of claim 11, wherein:
the first linear filter section and the third linear filter section each comprise an immittance inverting bandpass filter having a first passband with a first center frequency; and
the second linear filter section comprised of an immittance inverting bandpass filter having a second passband with a second center frequency, different from the first center frequency.

17. The device of claim 16, wherein:
the first parametric coupling circuit is responsive to a first control signal to perform a first parametric frequency conversion to convert a signal frequency between a first frequency in the first passband and a second frequency in the second passband, and apply a first phase shift based on a phase of the first control signal;
the second parametric coupling circuit is responsive to a second control signal to perform a second parametric frequency conversion to convert a signal frequency between a first frequency in the first passband and a second frequency in the second passband, and apply a second phase shift based on a phase of the second control signal.

18. A device, comprising:
a superconducting signal routing circuit comprising:
a first hybrid coupler;
a second hybrid coupler;
a first parametric multipole bandpass filter circuit and a second multipole bandpass filter circuit coupled, in parallel, to and between the first hybrid coupler and the second hybrid coupler;
wherein the first parametric multipole bandpass filter circuit comprises:
a first linear filter section, a second linear filter section, and a third linear filter section;
a first parametric coupling circuit which parametrically couples the first linear filter section and the second linear filter section; and
a second parametric coupling circuit which parametrically couples the second linear filter section and the third linear filter section.

19. The device of claim 18, wherein the second multipole bandpass filter circuit comprises a linear multipole bandpass filter circuit.

20. The device of claim 18, wherein the second multipole bandpass filter circuit comprises a second parametric multipole bandpass filter circuit, which is nominally identical in circuit architecture to the first parameter multipole bandpass filter circuit.
